(19) United States
(12) Patent Application Publication
(10) Pub. No.: US 2026/0261253 A1
(43) Pub. Date: Sep. 3, 2026

(54) LATERALLY-EXCITED BULK ACOUSTIC WAVE RESONATOR AND FILTER DEVICE INCLUDING THE SAME

(71) Applicant: Murata Manufacturing Co., Ltd., Nagaokakyo-shi (JP)

(72) Inventors: Sean MCHUGH, Santa Barbara, CA (US); Greg DYER, Santa Barbara, CA (US); Albert CARDONA, Santa Barbara, CA (US); Drew MOROSIN, Oxnard, CA (US)

(21) Appl. No.: 19/635,742

(22) Filed: Mar. 31, 2026

Related U.S. Application Data
(63) Continuation-in-part of application No. 19/025,547, filed on Jan. 16, 2025.
(60) Provisional application No. 63/623,117, filed on Jan. 19, 2024.

(51) Int. Cl. H03H 9/17; H03H 9/02; H03H 9/13; H03H 9/56

(52) U.S. Cl. CPC H03H 9/174; H03H 9/02031; H03H 9/02102; H03H 9/02228; H03H 9/132; H03H 9/176; H03H 9/562; H03H 9/564; H03H 9/568

(57) ABSTRACT

An acoustic resonator is provided that includes a substrate including a base and a cavity extending in a thickness direction thereof; and a piezoelectric layer coupled to the substrate. Moreover, the piezoelectric layer includes a plurality of nanowire structures that each include a piezoelectric bar that extends in a first direction over the cavity, and a pair of electrodes, each electrode of the pair of electrodes disposed on an opposite side of the piezoelectric bar to sandwich the piezoelectric bar in a second direction that is substantially perpendicular to the first direction and substantially orthogonal to a thickness direction of the substrate. At least two neighboring nanowire structures of the plurality of nanowire structures have a gap therebetween in the second direction.

### CROSS REFERENCE TO RELATED APPLICATIONS

This application is a continuation-in-part of U.S. patent application Ser. No. 19/025,547, filed Jan. 16, 2025, which claims the benefit of priority to U.S. Provisional Patent Application No. 63/623,117 filed on Jan. 19, 2024, the entire contents of each of which are incorporated herein by reference in their entirety.

### TECHNICAL FIELD

This disclosure relates to film bulk acoustic resonators and also to filters including film bulk acoustic resonators for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

### SUMMARY

In an exemplary aspect, an acoustic resonator is provided that includes a substrate including a base and a cavity extending in a thickness direction thereof; and a piezoelectric layer coupled to the substrate. In this aspect, the piezoelectric layer includes a plurality of nanowire structures that each comprise a piezoelectric bar that extends in a first direction over the cavity, and a pair of electrodes, each electrode of the pair of electrodes disposed on an opposite side of the piezoelectric bar to sandwich the piezoelectric bar in a second direction that is substantially perpendicular to the first direction and substantially orthogonal to a thickness direction of the substrate. Moreover, at least two neighboring nanowire structures of the plurality of nanowire structures have a gap therebetween in the second direction.

In another exemplary aspect of the acoustic resonator, adjacent neighboring electrodes of the at least two neighboring nanowire structures that face each other across the gap are configured to have opposite polarities from each other.

In another exemplary aspect of the acoustic resonator, adjacent neighboring electrodes of the at least two neighboring nanowire structures that face each other across the gap are configured to have a same polarity as each other. Moreover, for the at least two neighboring nanowire structures that face each other across the gap, a metal layer can extend on sidewalls of the respective piezoelectric bars and in the gap to face each other to form the adjacent neighboring electrodes of the at least two neighboring nanowire structures.

In another exemplary aspect of the acoustic resonator, all sidewalls in the gap are covered by the metal layer.

In another exemplary aspect of the acoustic resonator, a metal layer on a sidewall of a respective piezoelectric bar that forms at least one electrode of the pair of electrodes of at least one nanowire structure of the plurality of nanowire structures extends over the respective piezoelectric bar to partially overlap a top surface of the piezoelectric bar.

In another exemplary aspect of the acoustic resonator, a metal layer on a sidewall of a respective piezoelectric bar that forms at least one electrode of the pair of electrodes of at least one nanowire of the plurality of nanowires aligns to the piezoelectric bar relative to the thickness direction.

In another exemplary aspect of the acoustic resonator, a pitch of the plurality of nanowire structures varies in the second direction.

In another exemplary aspect, the acoustic resonator further comprises a dielectric layer on at least one electrode of the pair of electrodes opposite the respective piezoelectric bar of at least one nanowire structure of the plurality of nanowire structures.

In another exemplary aspect of the acoustic resonator, the substrate further comprises at least one intermediate layer having the cavity, the piezoelectric layer is coupled to the substrate via the at least one intermediate layer, and the piezoelectric bar of at least a portion of the plurality of nanowire structures extends over the cavity in the thickness direction.

A bandpass filter is provided according to another exemplary aspect that includes a plurality of acoustic resonators. At least one acoustic resonator of the plurality of acoustic resonators includes a substrate including a base and a cavity extending in a thickness direction thereof; and a piezoelectric layer coupled to the substrate. The piezoelectric layer includes a plurality of nanowire structures that each comprise a piezoelectric bar that extends in a first direction over the cavity, and a pair of electrodes, each electrode of the pair of electrodes disposed on an opposite side of the piezoelectric bar to sandwich the piezoelectric bar in a second direction that is substantially perpendicular to the first direction and substantially orthogonal to a thickness direction of the substrate. Moreover, at least two neighboring nanowire structures of the plurality of nanowire structures have a gap therebetween in the second direction.

A radio frequency module is provided in another exemplary aspect that includes a filter device including a plurality of acoustic resonators; and a radio frequency circuit coupled to the filter device, the filter device and the radio frequency circuit being enclosed within a common package. At least one acoustic resonator of the plurality of acoustic resonators of the filter device includes a substrate including a base and a cavity extending in a thickness direction thereof; and a piezoelectric layer coupled to the substrate. The piezoelectric layer includes a plurality of nanowire structures that each comprise a piezoelectric bar that extends in a first direction over the cavity, and a pair of electrodes, each electrode of the pair of electrodes disposed on an opposite side of the piezoelectric bar to sandwich the piezoelectric bar in a second direction that is substantially perpendicular to the first direction and substantially orthogonal to a thickness direction of the substrate. Moreover, at least two neighboring nanowire structures of the plurality of nanowire structures have a gap therebetween in the second direction.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1 illustrates a schematic plan view and schematic cross-sectional views of a Y-cut film bulk acoustic resonator (YBAR) according to an exemplary aspect.

FIG. 2A illustrates a schematic plan view and schematic cross-sectional views of a YBAR according to another exemplary aspect.

FIG. 2B illustrates a schematic plan view and schematic cross-sectional views of a variation of the YBAR shown in FIG. 2A according to another exemplary aspect.

FIG. 3A is a schematic cross-sectional view of a YBAR according to an exemplary aspect.

FIG. 3B is an alternative schematic cross-sectional view of a YBAR according to an exemplary aspect.

FIG. 4A illustrates a schematic plan view and a perspective view of an acoustic resonator structure that is a refinement of the exemplary aspect of the YBAR shown in FIG. 2A. FIG. 4B illustrates a cross-section view of the IDT configuration in FIG. 4A.

FIG. 5 illustrates a schematic plan view and a perspective view of an IDT configuration of another refinement of the exemplary aspect of the YBAR shown in FIG. 2A.

FIG. 6 illustrates a top view of the IDT configuration in FIGS. 4A and 4B according to an exemplary aspect.

FIGS. 7A and 7B illustrate graphs of an admittance [y] as a function of frequency of the acoustic resonator according to an exemplary aspect.

FIG. 8 illustrates a top view of another IDT configuration of the acoustic resonators shown in FIGS. 4A and 4B according to an exemplary aspect.

FIGS. 9A and 9B illustrate graphs of an admittance [y] as a function of frequency of an acoustic resonator as shown in FIG. 8 according to an exemplary aspect.

FIG. 10 illustrates a cross-sectional view of an IDT finger of an acoustic resonator configuration as shown in either FIG. 4A and/or FIG. 5 according to exemplary aspects.

FIG. 11A illustrates a graph of an admittance [y] as a function of frequency of an acoustic resonator according to an exemplary aspect.

FIG. 11B illustrates a graph of the coupling coefficient as a function of an aspect ratio of an acoustic resonator according to an exemplary aspect.

FIG. 12A illustrates a cross-sectional view of an IDT finger of an acoustic resonator configuration as shown in FIG. 8 according to an exemplary aspect.

FIGS. 12B and 12C illustrate graphs of an admittance [y] as a function of frequency of an acoustic resonator according to an exemplary aspect.

FIGS. 13A-13B compare energy/acoustic damping in metal layers according to an aspect of the disclosure.

FIG. 14 shows an example of a multi-layer metal structure for a first conductor pattern disposed on a first surface of a piezoelectric layer and for a second conductor pattern disposed on a second surface of the piezoelectric layer of an acoustic resonator structure according to an aspect of the disclosure.

FIGS. 15A-15C show displacements, stresses, and energies of three electrode structures, respectively according to an aspect of the disclosure.

FIGS. 16A-16C show an fd plot, a Qm plot, and a k2 plot, respectively, for an acoustic resonator ARN that has a 2-layer electrode structure shown in FIG. 14 according to an aspect of the disclosure.

FIG. 17 shows simulated results of displacements (“D”), stresses (“S”), and energies (“E”) of nine electrode structures, respectively according to an aspect of the disclosure.

FIG. 18A shows an fd plot indicating how the parameter fd varies with Cₘ/C_{LN} and ρₘ/ρ_{LN} according to an aspect of the disclosure.

FIG. 18B shows a Qm plot indicating how the parameter Qm varies with Cₘ/C_{LN} and ρₘ/ρ_{LN} according to an aspect of the disclosure.

FIG. 18C shows a k2 plot indicating how the parameter k2 varies with Cₘ/C_{LN} and ρₘ/ρ_{LN} according to an aspect of the disclosure.

FIGS. 19A-19C, 20A-20C, and 21A-21C show the effect of different metal materials as TE1 and BE1 according to an aspect of the disclosure.

FIG. 22A is a schematic block diagram of a filter using acoustic resonators according to an exemplary aspect.

FIG. 22B is a schematic diagram of a radio frequency module that includes an acoustic wave filter of FIG. 22A according to an exemplary aspect.

FIGS. 23A-23D show a plan view and cross-sectional views of an acoustic resonator structure according to an exemplary aspect of the disclosure.

FIGS. 24A-24C show a plan view and cross-sectional views of an acoustic resonator structure according to an exemplary aspect of the disclosure.

FIGS. 25A-25C show a plan view and cross-sectional views of an acoustic resonator structure according to an exemplary aspect of the disclosure.

FIG. 26 shows a cross-sectional view of an acoustic resonator structure according to an exemplary aspect of the disclosure.

FIG. 27 shows a cross-sectional view of an acoustic resonator structure according to an exemplary aspect of the disclosure.

FIGS. 28A-28G show cross-sectional views of an acoustic resonator structure according to some exemplary aspects of the disclosure.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator.

### DETAILED DESCRIPTION

Various aspects of the disclosed film bulk acoustic resonator, filter device and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

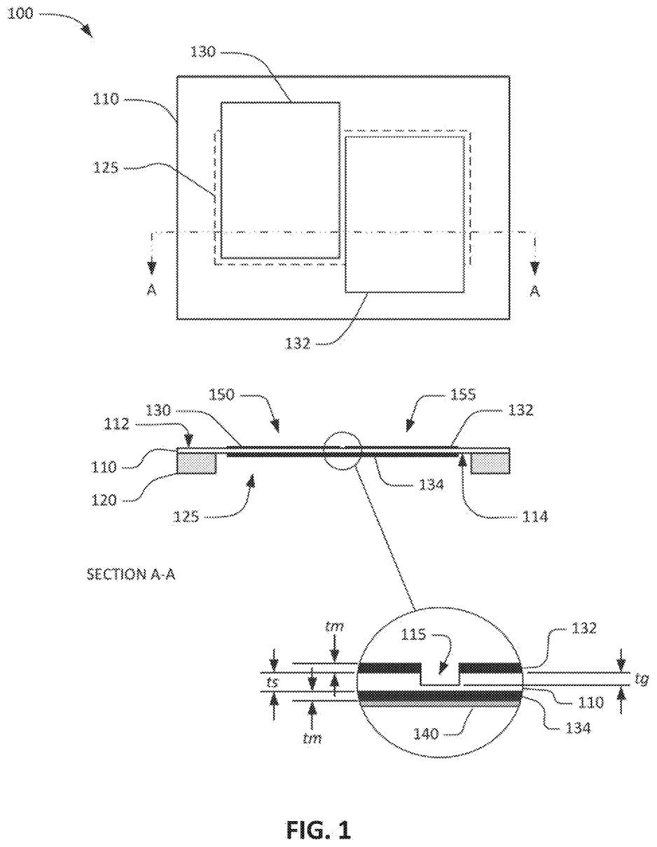

FIG. 1 shows a simplified top view and a cross-sectional view of a Y-cut film bulk acoustic resonator (YBAR) 100 according to an exemplary aspect. According to this aspect, the YBAR 100 includes a piezoelectric layer 110 (piezoelectric plate or piezoelectric layer may be used interchangeably) having essentially parallel front and back surfaces 112, 114, respectively. In this context, “essentially parallel” means “as close to parallel as possible” or “parallel within reasonable manufacturing tolerances.” Thus, it should be appreciated that the term “parallel” generally refers to the front side 112 and back side 114 opposing each other and that the surfaces may not be strictly planar and parallel to each other in an exemplary aspect. For example, due to the manufacturing variances resulting from the deposition process, the front side 112 and back side 114 may have undulations of the surface as would be appreciated to one skilled in the art. In addition, the piezoelectric layer 110 can be a thin single-crystal layer of a piezoelectric material. The term “single-crystal” does not necessarily mean entirely of a uniform crystalline structure and may include impurities due to manufacturing variances as long as the crystal structure is within acceptable tolerances.

According to the exemplary aspect, the piezoelectric layer 110 is preferably _{lithium niobate} (LN), but may be _{lithium tantalate} (LT), _{lanthanum gallium silicate}, gallium nitride, or some other material. The piezoelectric layer 110 is cut such that the orientation of the X, Y, and Z crystalline axes with respect to the front and back surfaces is known and consistent.

In an exemplary aspect, the thickness ts of the piezoelectric layer 110 may be determined from:

ts≈n*V_{SH}/2F_{R},

where F_{R} is a desired operation frequency, V_{SH} is the shear wave velocity of the piezoelectric layer, and n=1, 3, 5, . . . is the desired mode (overtone) number. In this regard, n=1 is usually referred to as “fundamental mode” and n>1 are referred to as “overtones”.

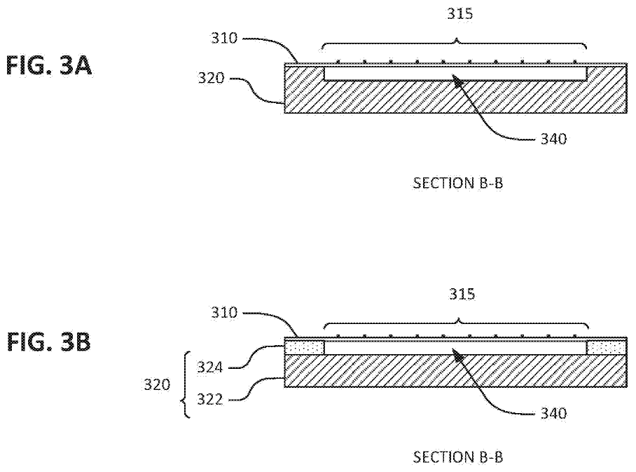

The back side 114 of the piezoelectric layer 110 is attached to a substrate 120 that provides mechanical support to the piezoelectric layer 110. The substrate 120 may be, for example, silicon, sapphire, quartz, or some other material. The piezoelectric layer 110 may be bonded to the substrate 120 using a wafer bonding process, or grown on the substrate 120, or attached to the substrate in some other manner. The piezoelectric layer 110 may be attached directly to the substrate or may be attached to the substrate via one or more intermediate material layers as discussed below with respect to FIGS. 3A and 3B. In other words, the back side 114 of the piezoelectric layer 110 can be coupled or connected either directly or indirectly, via one or more intermediate layers (e.g., a dielectric layer), to a surface of the substrate 120. Moreover, the phrase “supported by” or “attached” may, as used herein interchangeably, means attached directly, attached indirectly, mechanically supported, structurally supported, or any combination thereof.

A cavity 125 is formed in the substrate 120 such that the portion of the piezoelectric layer 110 containing the front-side and back-side conductor patterns 130, 132, 134 is suspended over the cavity 125. The portion of the piezoelectric layer 110 that is over (e.g., spanning or extending over) the cavity can be referred to herein as a “diaphragm” due to its physical resemblance to the diaphragm of a microphone. The diaphragm can be contiguous with the rest of the piezoelectric layer 110 around all of a perimeter of the cavity 125. In this context, “contiguous” means “continuously connected without any intervening item”. However, the diaphragm can be configured with at least 50% of the edge surface of the diaphragm coupled to the edge of the piezoelectric layer 110 in an exemplary aspect.

According to an exemplary aspect, “cavity” has its conventional meaning of “an empty space within a solid body.” The cavity 125 may be a hole completely through the substrate 120 (as shown in Section A-A) or a recess in the substrate 120 that does not extend through the substrate 120. The cavity 125 may be formed, for example, by selective etching of the substrate 120 before or after the piezoelectric layer 110 and the substrate 120 are attached. In some cases, the cavity 125 is not formed in the substrate 120, but instead the cavity is formed in one or more intermediate layers between the piezoelectric layer 110 and the substrate 120. In some cases, the cavity 125 is only partially formed in the substrate 120 and may also be partially formed in one or more intermediate layers between the piezoelectric layer 110 and the substrate 120. Moreover, as shown in FIG. 1, the cavity 125 has a rectangular shape. However, the cavity of YBAR 100 may have a different shape, such as a regular or irregular polygon. The cavity of YBAR 100 may have more or fewer than four sides, which may be straight or curved.

A first front-side conductor pattern 130 (e.g., a first electrode) and a second front-side conductor pattern 132 (e.g., a second electrode) are formed on the front side 112 of the piezoelectric layer 110. A back-side conductor pattern 134 (e.g., a floating electrode) is formed on the second side 114 of the piezoelectric layer 110. The back-side conductor pattern 134 is a “floating” conductor pattern, meaning that is not electrically connected to any other conductor. Moreover, the back-side conductor pattern 134 is capacitively coupled to the first and second front-side conductor patterns 130, 132. The conductor patterns may be molybdenum, aluminum, copper, gold, or some other conductive metal or alloy. The back-side conductor pattern and the front side conductor patterns are not necessarily the same material. In an exemplary aspect, the back-side conductor pattern 134 can be made of any appropriate electrically conductive material. For example, the back-side electrode may be gold to avoid corrosion. The portion of the piezoelectric layer 110 between the first front-side conductor pattern 130 and the back-side conductor pattern 134 forms a first resonator 150. The portion of the piezoelectric layer 110 between the second front-side conductor pattern 132 and the back-side conductor pattern 134 forms a second resonator 155. The first and second resonators 150, 155 are electrically in series such that an RF signal applied between the first and second front-side conductor patterns 130, 132 excites acoustic waves in both the first and second resonators 150, 155.

According to an exemplary aspect, the diaphragm forms a seal over the cavity 125 such that the first and second front-side conductor patterns 130, 134 are not exposed to the environment adjacent to the back-side conductor pattern 134. Ideally, when an RF signal is applied between the first and second front-side conductor patterns 130, 132, the back-side conductor pattern should remain at ground potential. To this end, a capacitance of the first resonator 150 should be equal to a capacitance of the second resonator 155. Assuming the piezoelectric diaphragm has uniform thickness, the capacitances will be equal if the area of the first resonator 150, which is to say the area of overlap between the first front-side conductor pattern 130 and the back-side conductor pattern 134, is equal to the area of the second resonator 155 which is the area of overlap between the second front-side conductor pattern 132 and the back-side conductor pattern 134. The back-side conductor pattern 134 will remain at ground potential when balanced signals (i.e., signals with equal amplitude and 180-degree phase difference), are applied to the first and second conductor patterns 130, 132. Moreover, one or more additional layers 140 can be disposed on the back-side conductor pattern 134 that is opposite the piezoelectric layer 110. The one or more additional layers 140 can be a dielectric layer, a sensor layer or the like, that can convert the resonator to a sensor in an exemplary aspect. For example, a sensing layer 140 may be provided, for example, as a film, a monolayer, or a surface treatment that is either disposed directly on the back-side conductor pattern 134 or may be coupled to the back-side conductor pattern 134 via one or more additional an intermediate layers, such as an adhesion layer.

According to the exemplary aspect, the piezoelectric layer 110 may be Y-cut (i.e., with the Y crystalline axis of the piezoelectric material normal to the surfaces 112, 114) or rotated Y-cut (i.e., with the Y crystalline axis of the piezoelectric material rotated by a predetermined angle with respect to normal to the surfaces 112, 114). In this case, an RF signal applied between the first and second front-side conductor patterns 130, 132 will excite shear acoustic waves in both the first and second resonators 150 and 155. Rotated Y-cuts can be used to achieve shear displacements exclusively in planes parallel to the surface 112, 114. Selection of the rotation angle can be used to control the electromechanical coupling of the resonators. Shear displacements parallel to the surfaces of the piezoelectric layer do not generate compressional waves in an adjacent liquid thus allowing high Q-factor operation of the resonator.

As shown in FIG. 1, the first and second front-side conductor patterns 130 and 132 and the back-side conductor pattern 134 are rectangular in shape. However, the conductor patterns may be non-rectangular (e.g., trapezoidal, curved, or irregular) to suppress parasitic acoustic modes according to alternative aspects.

In the detailed cross-sectional view, the thickness of the piezoelectric layer 110 is dimension ts and the thickness of the conductor patterns 130, 132, 134 is dimension tm. The thickness ts of the piezoelectric layer 110 may be, for example, 100 nanometers (nm) to 1000 nm according to an exemplary aspect. Moreover, the thickness tm of the conductor patterns 130, 132, 134 may be, for example, 10 nm to 500 nm. The thickness of the conductor patterns may be the same or the first and second front-side conductor patterns 130 and 132 and the back-side conductor pattern 134 may have different thicknesses from each other in an exemplary aspect.

As further shown, the piezoelectric layer may be etched or otherwise removed, completely or only partially, in the area between the first and second front-side conductor patterns 130, 132, forming slots 115. The presence of the slots 115 may suppress lateral acoustic modes that might be excited by the electric field between the front-side conductor patterns 130, 132. A depth tg of the slot 115 can extend partially or completely through the piezoelectric layer 110.

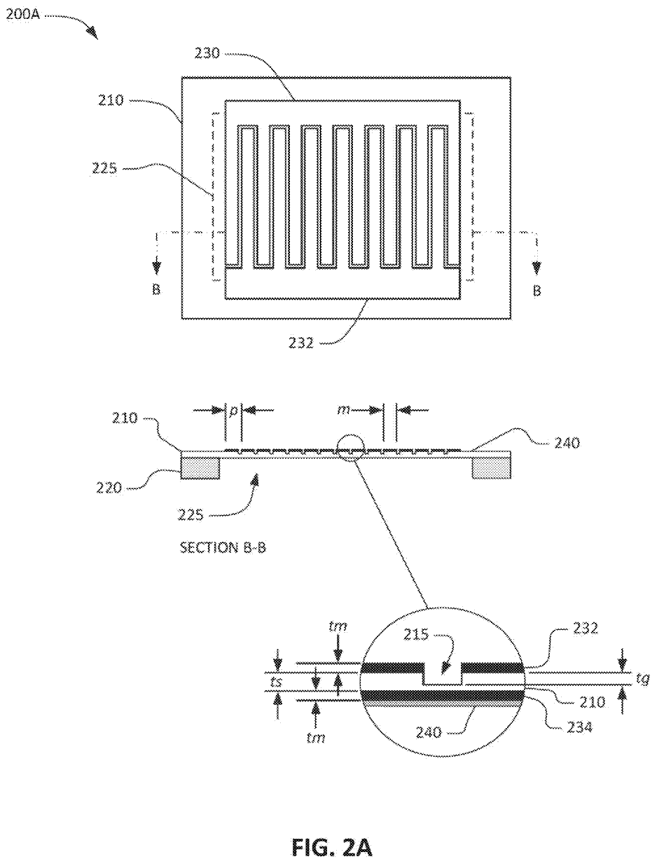

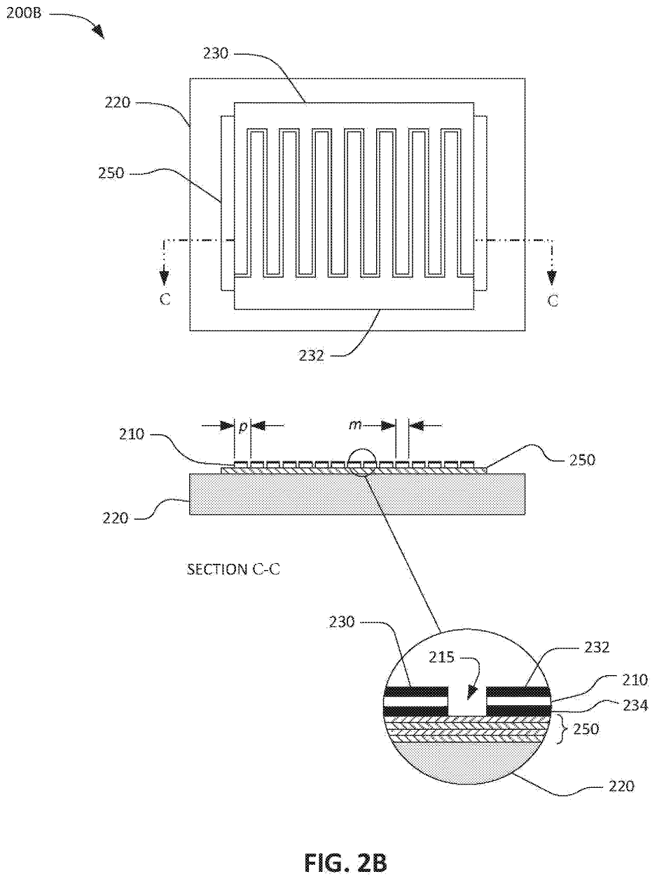

FIG. 2A shows a simplified top view and a cross-sectional view of another YBAR 200A. The YBAR 200A is made up of a piezoelectric layer 210 attached to a substrate 220 as previously described. A cavity 225 (identified by dashed lines) is formed in the substrate 220 such that a portion of the piezoelectric layer 210 is suspended over the cavity 225.

First and second front-side conductor patterns 230, 232 (e.g., first and second electrodes) are formed on the front side of the piezoelectric layer (the side facing away from the cavity 225). The first and second front-side conductor patterns 230, 232 form an interleaved finger pattern (IFP) similar to an interdigital transducer or IDT used in surface acoustic wave resonators. The first front-side conductor pattern 230 includes a first plurality of parallel fingers extending (e.g., substantially parallel) from a first busbar. The second front-side conductor pattern 232 includes a second plurality of parallel fingers extending (e.g., substantially parallel) from a second busbar. The first and second pluralities of parallel fingers are interleaved and most or all of the interleaved parallel fingers are disposed on the portion of the piezoelectric layer 210 that is over the cavity 225. The width m of each finger will be a substantial portion of the pitch p, or center-to-center spacing, between at least a pair of interleaved fingers extending from different busbars.

As shown in the detail view, slots 215 may be formed in the piezoelectric layer 210 between the interleaved fingers of the first and second front-side conductor patterns 230, 232 in an exemplary aspect. The presence of the slots 215 may suppress lateral acoustic modes that might be excited by the electric field between the front-side conductor patterns 230, 232. A depth tg of the slots 215 can extend partially or completely through the piezoelectric layer 210. The grooves also prevent spreading of vibration energy along the structure thus improving Q-factor of resonators.

A back-side conductor pattern 234 is formed on the back side of the piezoelectric layer 210 opposed to the first and second front-side conductor patterns 230, 232. A first resonator is formed between the first front-side conductor pattern 230 and the backside conductor pattern 234. A second resonator is formed between the second front-side conductor pattern 232 and the back-side conductor pattern 234. The first and second front-side conductor patterns may have the same number of interleaved fingers in an exemplary aspect. Moreover, one or more additional layers 240 can be disposed on the back-side conductor pattern 234 that is opposite the piezoelectric layer 210. The one or more additional layers 240 can be a dielectric layer, a sensor layer or the like to convert the resonator to a sensor in an exemplary aspect. For example, the sensing layer 240 may be, for example, a film, a monolayer, or a surface treatment that is either disposed directly on the back-side conductor pattern 234 or may be coupled to the back-side conductor pattern 234 via one or more additional an intermediate layers, such as an adhesion layer.

FIG. 2B illustrates a schematic plan view and schematic cross-sectional views of a variation of the YBAR shown in FIG. 2A according to another exemplary aspect. It is noted that the plan view of YBAR 200B generally comprises the same elements of YBAR 200A, which includes a piezoelectric layer 210 attached to a substrate 220, and first and second front-side conductor patterns 230, 232, as previously described.

However, instead of having a cavity, YBAR 200B includes an acoustic Bragg reflector 250 that is between (e.g., “sandwiched”) the substrate 220 and the back surface of the piezoelectric plate 210. The term “sandwiched” means the acoustic Bragg reflector 250 is both disposed between and physically connected to a surface of the substrate 220 and the back surface of the piezoelectric plate 210. In some circumstances, thin layers of additional materials may be disposed between the acoustic Bragg reflector 250 and the surface of the substrate 220 and/or between the acoustic Bragg reflector 250 and the back surface of the piezoelectric plate 210. Such additional material layers may be present, for example, to facilitate bonding the piezoelectric plate 210, the acoustic Bragg reflector 250, and the substrate 220.

According to the exemplary aspect, the acoustic Bragg reflector 250 includes multiple layers that alternate between materials having high acoustic impedance and materials having low acoustic impedance. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. In an exemplary aspect, each of the layers can have a thickness equal to, or about, one-fourth of the acoustic wavelength at or near a resonance frequency of the SM XBAR 200. Materials having comparatively low acoustic impedance include silicon dioxide, silicon oxycarbide, aluminum, titanium, and certain plastics such as cross-linked polyphenylene polymers. Materials having comparatively high acoustic impedance include silicon nitride, aluminum nitride, silicon carbide, and metals such as molybdenum, tungsten, gold, and platinum. All of the high acoustic impedance layers of the acoustic Bragg reflector 250 are not necessarily the same material, and all of the low acoustic impedance layers are not necessarily the same material.

An exemplary cross-sectional view is shown along the section plane C-C of YBAR 200B. As shown, a space 215 (e.g., a cavity) is defined or formed in the first and second front-side conductor patterns 230, 232 and the piezoelectric plate 210 to provide acoustic isolation between adjacent fingers. The space or cavity may be formed in the respective layers by etching or otherwise removed to effectively form slots as the cavity 215. The presence of the cavity 215 suppresses lateral acoustic modes that might be excited by the electric field between the front-side conductor patterns 230, 232.

FIG. 3A and FIG. 3B show two exemplary cross-sectional views along the section plane B-B defined in FIG. 2A of YBAR 200A. It is noted that the configurations of the substrate 320 shown in FIGS. 3A and 3B may also be implemented for the YBAR configuration shown in FIG. 1. In FIG. 3A, a piezoelectric layer 310, which corresponds to piezoelectric layer 210, is attached directly to a substrate 320, which can correspond to substrate 220 of FIG. 2A. Moreover, a cavity 340, which does not fully penetrate the substrate 320, is formed in the substrate under the portion (i.e., the diaphragm 315) of the piezoelectric layer 310 containing the interleaved fingers of the IDT of an YBAR. The cavity 340 can correspond to cavity 225 of FIG. 2A and/or the cavity 125 of FIG. 1. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. The intermediate layer 324 may, for example, be a dielectric layer. The intermediate layer 324 may be comprised of one or multiple layers between the base 322 and the piezoelectric layer 310. For example, the base 322 may be silicon (e.g., a silicon support substrate) and the intermediate layer 324 may be a silicon oxide or dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of a YBAR. In some cases, the cavity may be entirely disposed in the intermediate layer 324 with a portion of the intermediate layer 324 being attached to a portion (i.e., the diaphragm 315) of the piezoelectric layer 310 over the cavity 340. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310. A thin layer of dielectric (not shown) may also be on the underside of piezoelectric layer 310 that faces the intermediate layer 324 and encloses the cavity 340 in an exemplary aspect.

In this case, the diaphragm 315, which can correspond to the diaphragm of either of FIG. 1 and/or FIG. 2A, for example, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects. It is also noted while the exemplary aspect contemplates the resonator structures utility a membrane-based resonator structure, the resonator structures can be solidly mounted on metallic Bragg stack (mirror or reflector) for improved reliability in an alternative aspect, for example, using a configuration as described above with respect to FIG. 2B.

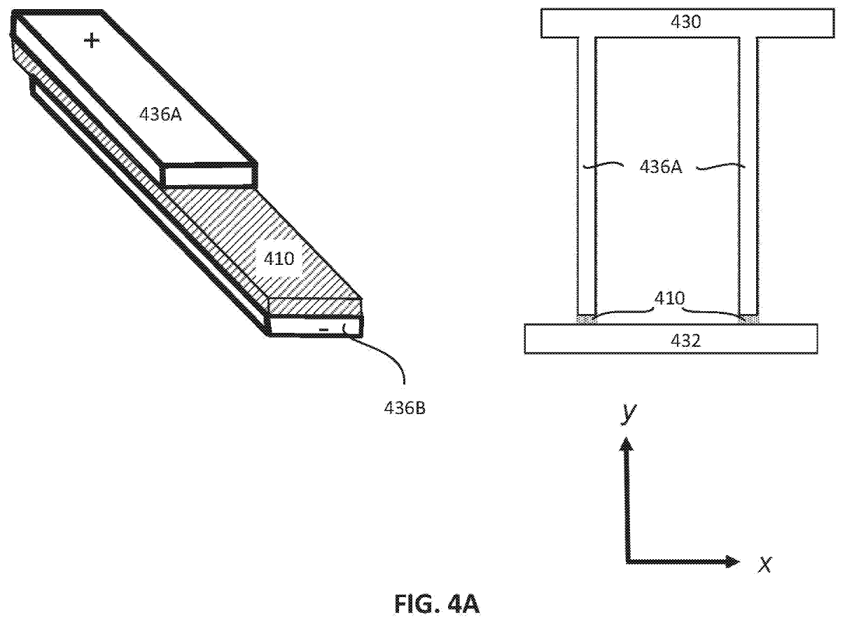

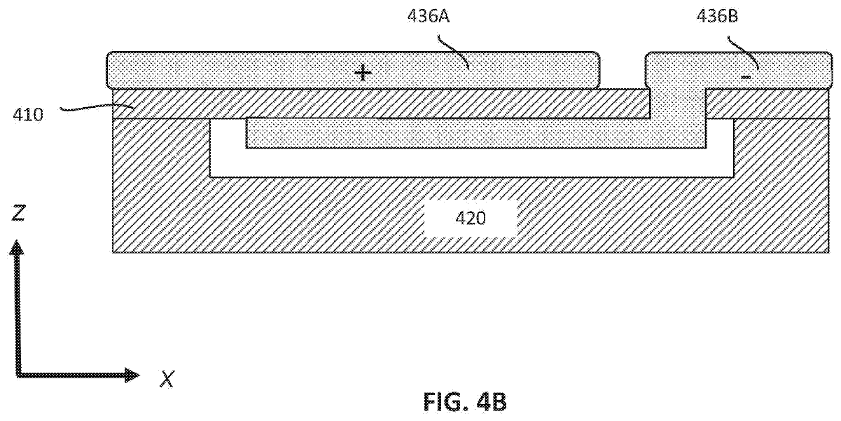

FIG. 4A illustrates a schematic plan view and a perspective view of an acoustic resonator structure that is a refinement of the exemplary aspect of the YBAR shown in FIG. 2A. It should be appreciated that the acoustic resonator structure shown in FIG. 4A can also be configured to have an acoustic Bragg reflector configuration as described above with respect to the YBAR configuration of FIG. 2B. The X and Y axes are shown relative to the plan view in FIG. 4A. FIG. 4B illustrates a cross-section view of the IDT configuration in FIG. 4A. The Z axis in FIG. 4B is orthogonal to the plane defined by the X and Y axes of FIG. 4A.

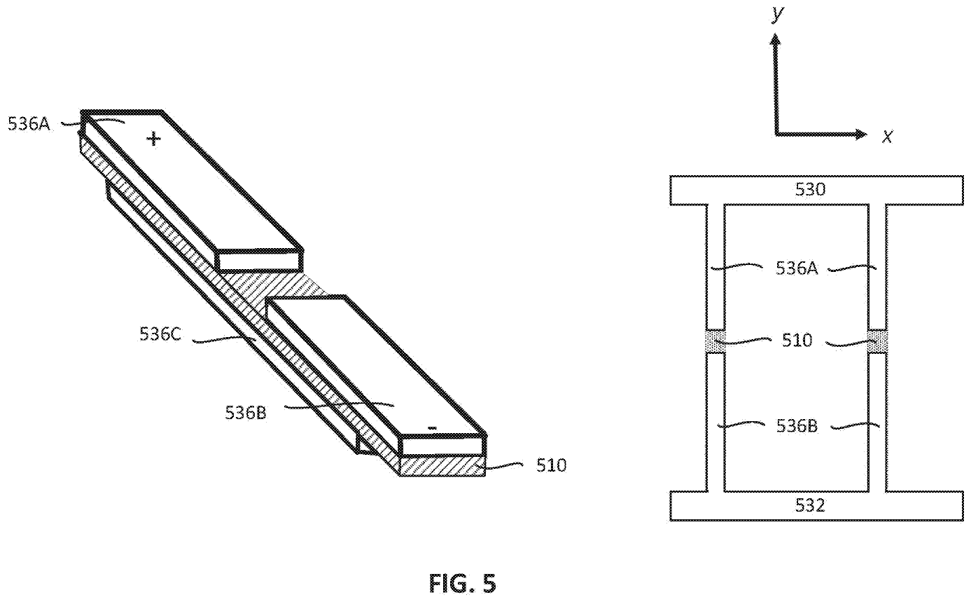

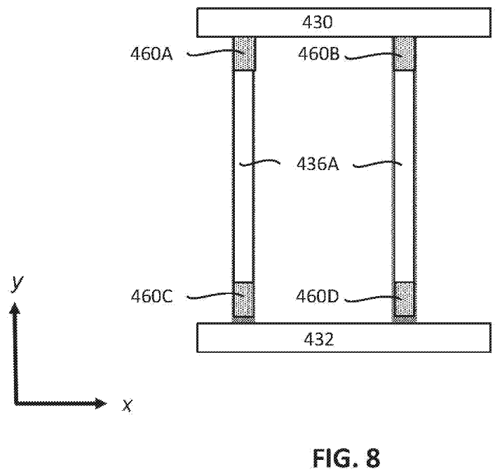

As shown, the electrode fingers (e.g., a pair) extend from a pair of busbars in a similar configuration as described above. In an exemplary aspect, the plurality of electrode fingers (also referred to as nanowires) each extend from a busbar predominantly in a first direction (e.g., substantially parallel to each other). Each of the electrode fingers includes an electrode 436A (e.g., a top or first electrode) with a first potential (e.g., a positive potential) extending from a first busbar 430 is on top (e.g., a first side) of the piezoelectric layer 410 and an electrode 436B (e.g., a bottom or second electrode) with a second potential (e.g., a negative potential) extending from a second busbar 432 is on the bottom (e.g., a second side) of the piezoelectric layer/material such that the electrode 436A on the top of the piezoelectric layer 410 at least partially overlaps the electrode 436B on the bottom of the piezoelectric layer 410. As should be readily appreciated, the top and bottom electrodes 436A and 436B having isolated piezoelectric between them, such that a cavity (e.g., an air gap or some sort of insulating material such as a dielectric) provides for increased isolation of each adjacent top and bottom electrode pair and an adjacent top and bottom electrode pair. The YBAR configuration described below with respect to FIG. 5 as well as the configuration having piston masses as shown in FIG. 8 can each have isolation between the respective electrode fingers as well.

It is noted that while the piezoelectric layer 410 is shown to have a same width in the X-direction as the first and second electrodes, the piezoelectric layer can have a larger width in the X direction in an alternative aspect, such that the electrodes have a smaller width than the piezoelectric layer (in the X-direction). The piezoelectric layer 410 can also have different cross-sectional shapes besides a rectangular shape, such as a hexagonal shape. Moreover, while the corners/edges of the piezoelectric layer 410 and the electrics are shown to have a 90 degree or right angle, it should be appreciated that these corners or edges can be rounded or curved in practice, which may result from the deposition and/or etching processes as would be appreciated to one skilled in the art. Yet further, it should be appreciated that the electrodes 436A and/or 436B could have a wider width (i.e., in the X-direction) than the piezoelectric layer 410 and that the top and bottom electrodes can also have different widths from one another. It should be appreciated that these configurations can be applied to each of the embodiments shown in FIGS. 4A, 4B, 5 and/or 8, for example.

FIG. 4B illustrates how the electrode 436B with the second potential extends into a cavity of the acoustic resonator, for example, cavity 125/225, as described above. This configuration is described as a McBAW resonator in an exemplary aspect. As noted above, the cavity can be disposed directly in the substrate as shown in FIG. 3A. Alternatively, the cavity can be disposed in an intermediate layer (e.g., a dielectric layer) between the substrate and the IDT structure as shown in FIG. 3B.

Thus, according to the exemplary aspect shown in FIGS. 4A and 4B, an acoustic resonator is provided that includes a substrate (e.g., a substrate 420 in FIG. 4B); a piezoelectric layer (e.g., the piezoelectric layer 410) coupled to the substrate either directly or via one or more intermediate layers; a first conductor pattern forming a plurality of first electrodes 436A disposed on a first surface of the piezoelectric layer (which has a first potential); and a second conductor pattern forming a plurality of second electrodes 436B disposed on a second surface of the piezoelectric layer 410 opposite the first surface (which has a second potential). In this aspect, the respective electrodes of the first and second conductor patterns with the piezoelectric layer disposed therebetween collectively form at least a pair of electrode fingers (also referred to as “acoustically resonant nanowires”) extending in a first direction from a busbar and acoustically isolated, or at least acoustically insulated, from each other by way of a cavity or space disposed between the adjacent nanowires (e.g., the electrode fingers). In some exemplary aspects, a pair of electrode fingers and the piezoelectric layer therebetween form an acoustically resonant nanowire (ARN) structure.

Thus, in the exemplary aspect, each of the plurality of nanowires extend from a busbar in a first direction (e.g., the y axis direction shown in FIG. 4A), such that a space is defined between the nanowires (e.g., at least a pair of nanowires of the plurality of nanowires) in a second direction (e.g., the x axis direction shown in FIG. 4A) that is substantially perpendicular to the first direction. In this regard, there is no piezoelectric material between the pair of nanowires in the second direction. In other words, as further illustrated in FIG. 4A, the conductor patterns and piezoelectric material may be removed in the x and y area between adjacent pairs of top and bottom electrodes such that the fingers (i.e., nanowires) formed by each top and bottom electrode pair are substantially acoustically isolated, or at least partially acoustically isolated from one another as the piezoelectric layer does not connect one finger to the next finger. Accordingly, the top and bottom electrodes having isolated piezoelectric between each top and bottom electrode can be isolated from an adjacent top and bottom electrodes having piezoelectric therebetween by a cavity (such as a space or an air gap), some sort of insulating material such as a dielectric, or any other arrangement that allows for increased isolation of each adjacent top and bottom electrode pair and an adjacent top and bottom electrode pair. An exemplary YBAR configurations having this acoustic isolation configuration is described above with respect to FIG. 2B, for example.

As described in more detail below, the pair of electrode fingers each comprise a width in a second direction that is substantially perpendicular to the first direction and a height in a thickness direction that is substantially orthogonal to the first and second directions. The ratio of the width to the height of each electrode finger is less than 2 in order to reduce spurs during excitation of the resonator device. As further shown, the acoustic resonator includes a pair of busbars (similar to the configuration described above), where a first busbar of the pair of busbars is coupled to the first conductor pattern, and a second busbar of the pair of busbars is coupled to the second conductor pattern. It is noted that the term “substantially” (e.g., “substantially perpendicular” and/or “substantially orthogonal”) means that the relative directions are generally perpendicular or orthogonal, but may vary slightly (e.g., by 10 degrees) to take into account minor tolerances for manufacturing variances.

FIG. 5 illustrates a schematic plan view and a perspective view of an IDT configuration of another refinement of the exemplary aspect of the YBAR shown in FIG. 2A. It should be appreciated that the acoustic resonator structure shown in FIG. 5 can also be configured to have an acoustic Bragg reflector configuration as described above with respect to the YBAR configuration of FIG. 2B. In either event, in the configuration of FIG. 5, the two electrodes 536A and 536B with positive and negative potentials are both on a first side (e.g., top side or surface) of the piezoelectric layer 510 whereas a floating electrode 536C is on the opposing (e.g., second) side (e.g., bottom side or surface) of the piezoelectric layer 510. A similar configuration is described above with respect to FIG. 1, except that this configuration includes a plurality (e.g., pair) of electrode fingers. The exemplary acoustic resonator structure shown in FIG. 5 is similar to that described above in FIGS. 4A and 4B, except that it provides for a YBAR configuration in which a first busbar 530 of the pair of busbars is coupled to the first conductor pattern (e.g., fingers 536A), and a second busbar 532 of the pair of busbars is coupled to the second conductor pattern (e.g., fingers 536B). Moreover, a floating conductor pattern is the floating electrode 536C that at least partially overlaps conductor patterns 536A and 536B. It is noted that while the piezoelectric layer 510 is shown to have a same width in the X-direction as the first and second electrodes, the piezoelectric layer 510 can have a larger width in the X direction in an alternative aspect.

According to the exemplary aspects in FIGS. 4A, 4B and 5, the acoustic resonators are configured such that an X-dimension of the fingers (i.e., the width in the X-direction) is reduced to a minimum to form a single pair of electrodes as shown therein. As a result, an array of electrode pairs can be arranged and since they are separated by vacuum, the electrode pairs are acoustically isolated, or at least partially acoustically isolated, from one another by way of space or a cavity between adjacent fingers since the piezoelectric material is limited to be between, or substantially between, the top and bottom electrodes. According to this configuration, when the X-dimension of the electrode fingers is reduced to a minimum, the physics become quasi-1D and the X-dependent spurs will occur only at high frequencies in operation.

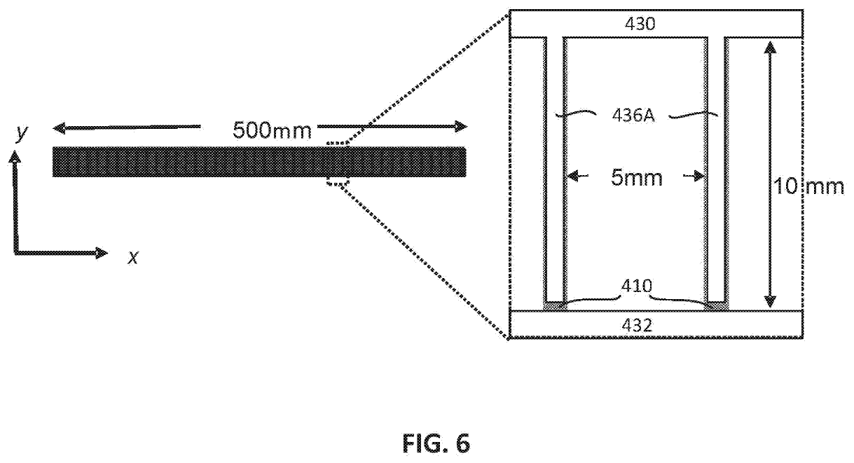

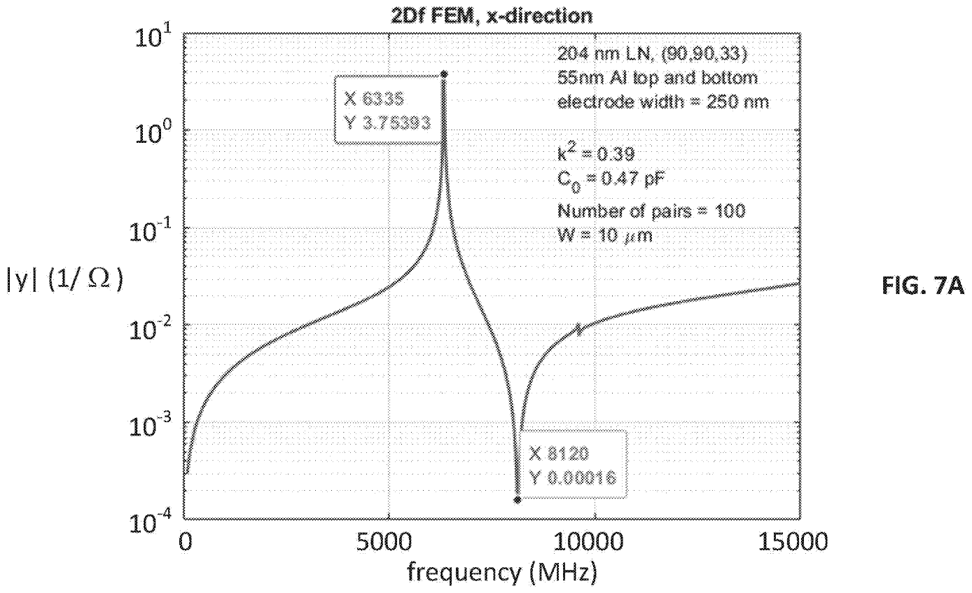

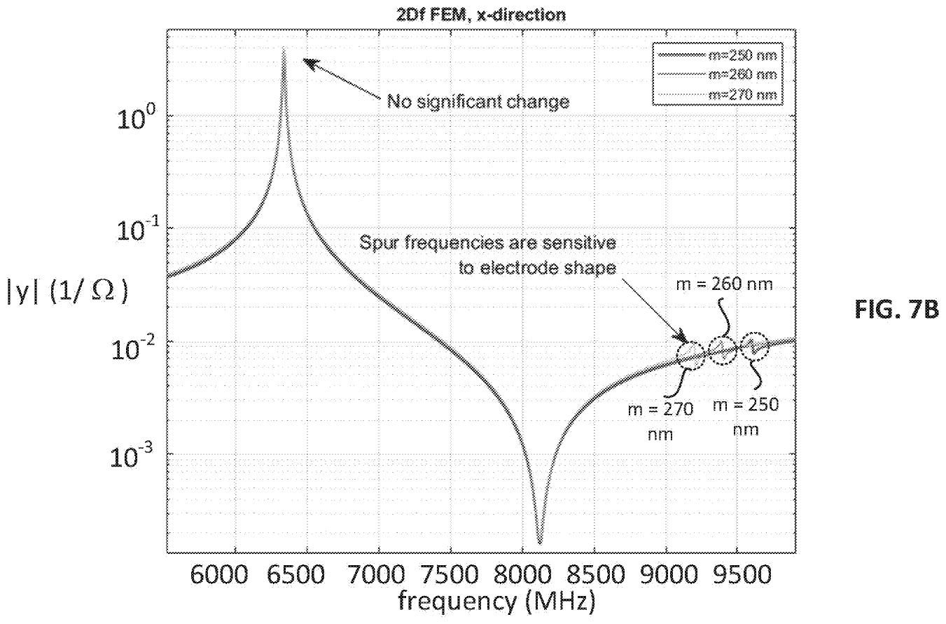

FIG. 6 illustrates a top view of the IDT configuration in FIGS. 4A and 4B according to an exemplary aspect. FIGS. 7A and 7B illustrate graphs of an admittance [y] as a function of frequency of an acoustic resonator according to an exemplary aspect.

According to an exemplary aspect, the piezoelectric layer 410 may comprise lithium niobate having Euler angles of (90, 90, 30±4). This configuration provides for a very high electromechanical coupling (i.e., k²≈0.39), which is sufficient for Wi-Fi full-band without inductors. FIG. 7A illustrates a two-dimensional (2D) simulation, which is simulated using finite element method (FEM) simulation techniques, for X-direction (2Dx) and illustrates admittance for an existing series resonator for WiFi-full band. It is also noted that the total area required by a resonator will depend on the etch process. FIG. 6 illustrates an estimation for the area required using 5 μm spacing between electrode pairs.

FIG. 7B illustrates 2Dx FEM simulations with various linewidths according to an exemplary aspect. It is noted that the resonance frequency is insensitive to electrode width, meaning that the resonance broadening will not be detrimental compared with XBAR. However, the spurs are sensitive to the width and side-wall angle. For XBAR, the electrode dimensions should be fabricated precisely to control the impact of spurs. According to the exemplary aspects, if the linewidth is sufficiently narrow, all X-direction spurs will only occur at high frequency (e.g., greater than 9000 MHz). Moreover, the X-direction spurs will also be smoothed by normal variations of the electrode widths.

FIG. 8 illustrates a top view of another IDT configuration of the acoustic resonators shown FIGS. 4A and 4B according to an exemplary aspect. In this aspect, piston masses 460A through 460D are disposed on tops of the ends of the electrode fingers 436A, respectively. The piston masses may be additional layers (e.g., metal) that are deposited adjacent the busbar 430 and on the free end of the electrodes 436A to address spurs. Thus, as shown, the acoustic resonator includes a pair of piston masses disposed on a top surface of the first conductor pattern forming the pair of electrode fingers. In an exemplary aspect, a first pair of piston masses 460A and 460B are disposed adjacent to a base (e.g., connection to busbar 430) and a second pair of piston masses 460C and 460D on a free end of each of the pair of electrode fingers 436A, respectively. The piston masses can generally be considered as an extra layer of metal, for example, that has a rectangular or square shape from a plan view thereof. Preferably, the piston masses 460A-D have a same width (i.e., in the X-direction) as the first and second conductor patterns 436A. The pairs of piston masses can be disposed on either the first conductor pattern and/or on both the first and second conductor patterns, such that they overlap each other in the plan view (i.e., the Z-direction).

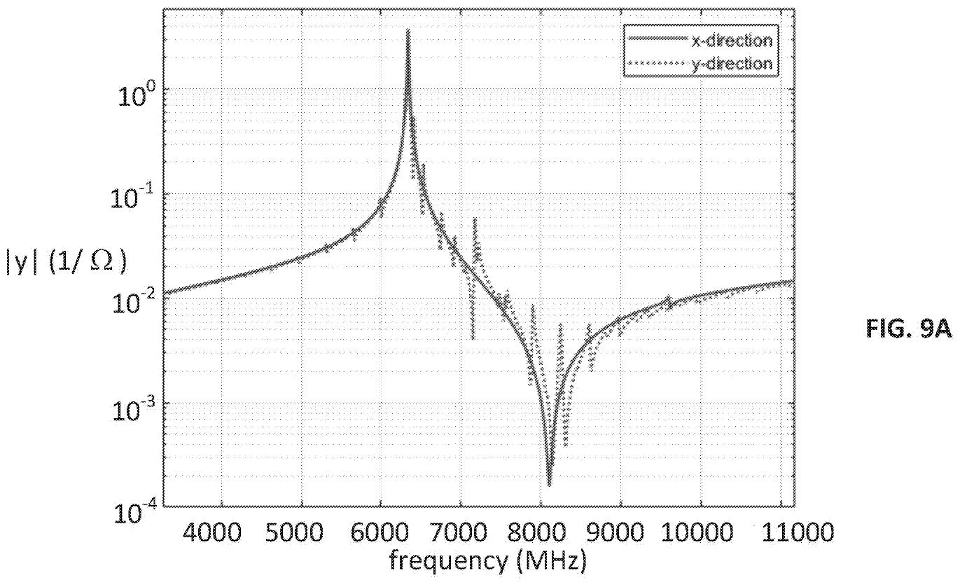

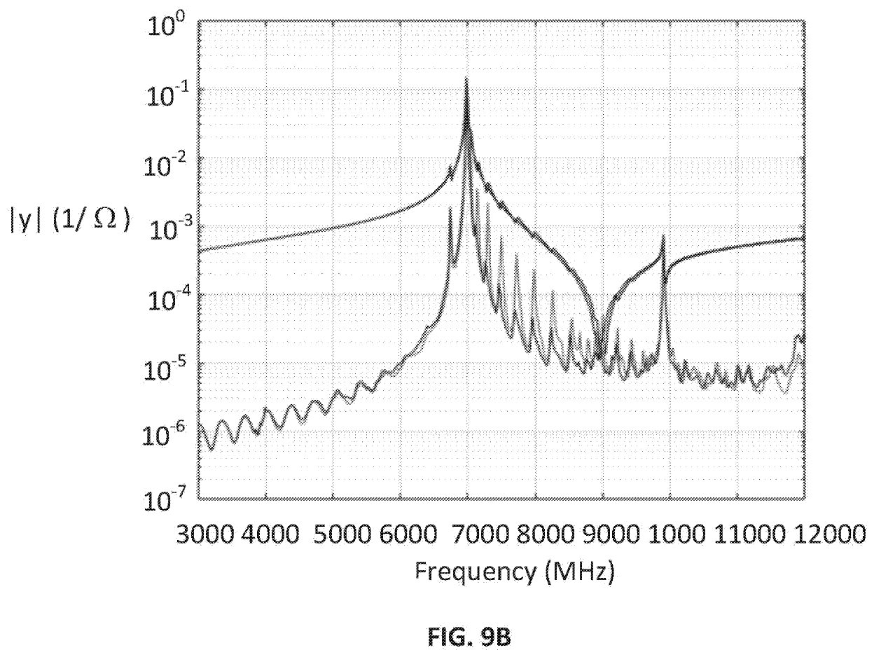

FIGS. 9A and 9B illustrate graphs of an admittance [y] as a function of frequency of an acoustic resonator as shown in FIG. 8 according to an exemplary aspect. These graphs are also simulated using finite element method (FEM) simulation techniques. According to an exemplary aspect, there may be significant spurs in the aperture (i.e., the Y-direction). However, the piston masses 460A-D are provided to suppress these spurs. FIG. 9A illustrates a 2Dy compared to 2Dx simulation and the additional cavity modes. According to the exemplary aspect, these transverse modes are suppressed by the piston masses 460A-D. FIG. 9B illustrates an exemplary aspect of the piston mode, which illustrates the reduction in spurs.

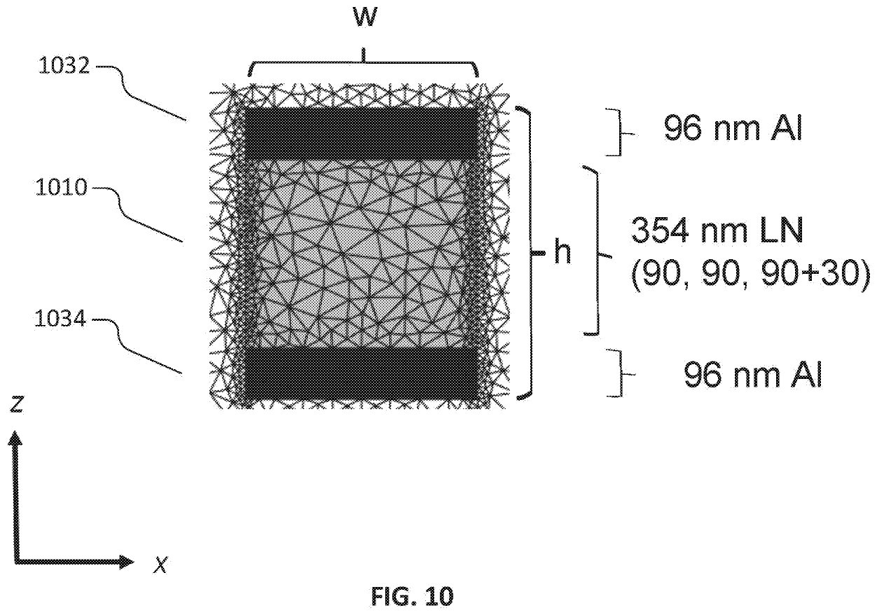

FIG. 10 illustrates a cross-sectional view of an IDT finger (e.g., an acoustically resonant nanowire) of an acoustic resonator configuration as shown in either FIG. 4A and/or FIG. 5 according to exemplary aspects. As should be appreciated, the exemplary electrode finger includes a first or top electrode 1032 and a second or bottom electrode 1034 with a piezoelectric layer 1010 disposed therebetween. According to the exemplary aspect, the width of at least one (or both) of the electrodes (e.g., denoted by width w in the X-direction) is less than two times the height in the thickness direction (e.g., denoted by height h in the Z-direction), where the height h is defined as the total height of the electrode fingers, i.e., the top electrode 1032, the bottom electrode 1034, and the piezoelectric layer 1010. In some cases, the thickness direction may be orthogonal to either the top or bottom surface of the piezo. However, either the top or bottom surface of the piezo may have variances due to manufacturing tolerances in which case the thickness direction may be substantially orthogonal (as orthogonal as possible) to either the top or bottom surface of the piezo. In any case, the height h of the electrode finger may be measured from, and including, the bottom electrode to, and including, the top electrode. The non-limiting example shown in FIG. 10 illustrates the top electrode 1032 and bottom electrode 1034 each having a height of 96nm and formed of aluminum. Moreover, the piezoelectric layer 1010 can be formed of lithium niobate and have a height of 354 nm.

Thus, according to the exemplary aspect, the ratio of x/z as shown in FIG. 10 is less than 2. Moreover, it is noted that the resonator performance is primarily set by the electrodes away from the piston masses (assuming they are included according to an exemplary aspect). As a result, it should be appreciated that if the aspect ratio x/z is less than 2, it will be smaller at the ends of the fingers where the piston masses are located (i.e., since the height increases). According to the exemplary aspect, the capacitance density is much higher than an XBAR structure due to a smaller active area. In addition, the thermal conductance is much higher due to metal that covers the top and bottom surfaces of the piezoelectric layer, so these effects may offset one another leaving the power-handling similar to XBAR.

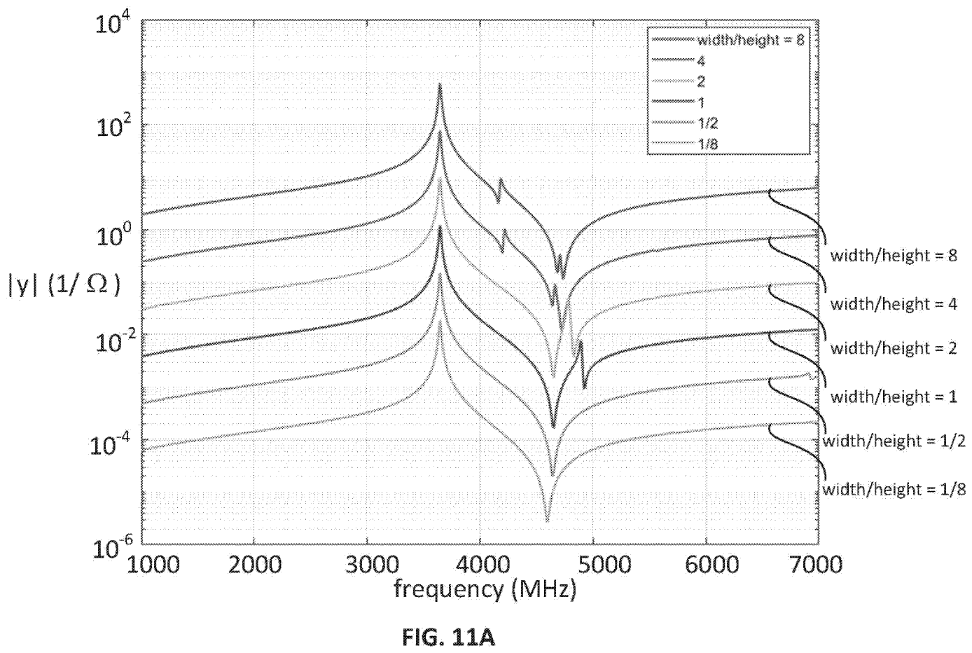

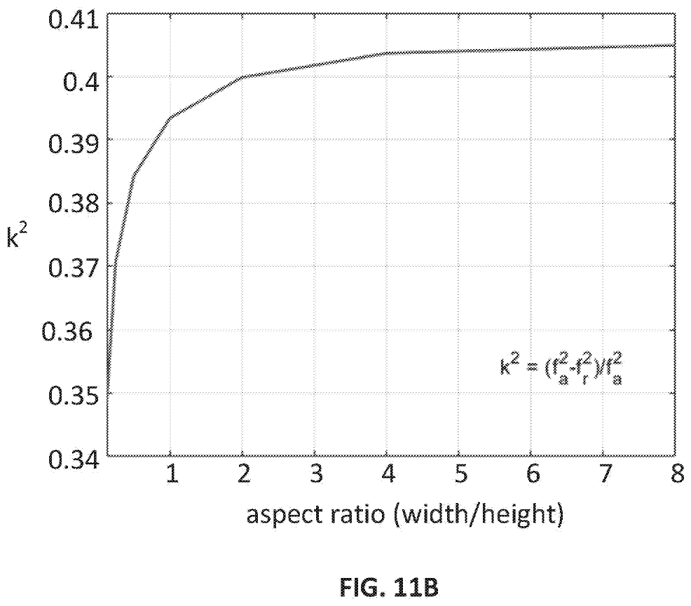

FIG. 11A illustrates a graph of an admittance [y] as a function of frequency of an acoustic resonator according to an exemplary aspect. FIG. 11B illustrates a graph of the coupling coefficient k² as a function of an aspect ratio of an acoustic resonator according to an exemplary aspect. These graphs are also simulated using finite element method (FEM) simulation techniques.

According to the exemplary aspects, the aspect ratio (i.e., the width/total height of the electrode structure) should be minimized to avoid spurs. FIG. 11A illustrates 2Dx FEM simulations with a fixed height and various widths. As shown, the acoustic resonator structures with smaller aspect ratio shift the X-direction spurs to higher frequencies. Thus, it should be appreciated that acoustic resonator structures according to the exemplary aspect with aspect ratios that are less than 1 are advantageous to minimize spurs. On the other hand, FIG. 11B illustrates that for very small aspect ratios, the coupling decreases. Thus, according to the exemplary aspect, the acoustic resonator structure preferably has an aspect ratio that is less than 2.

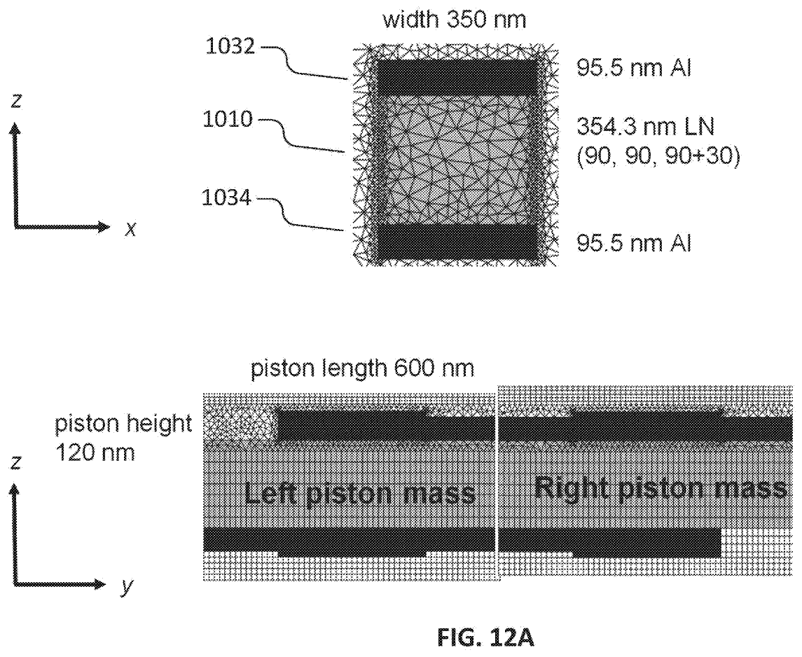

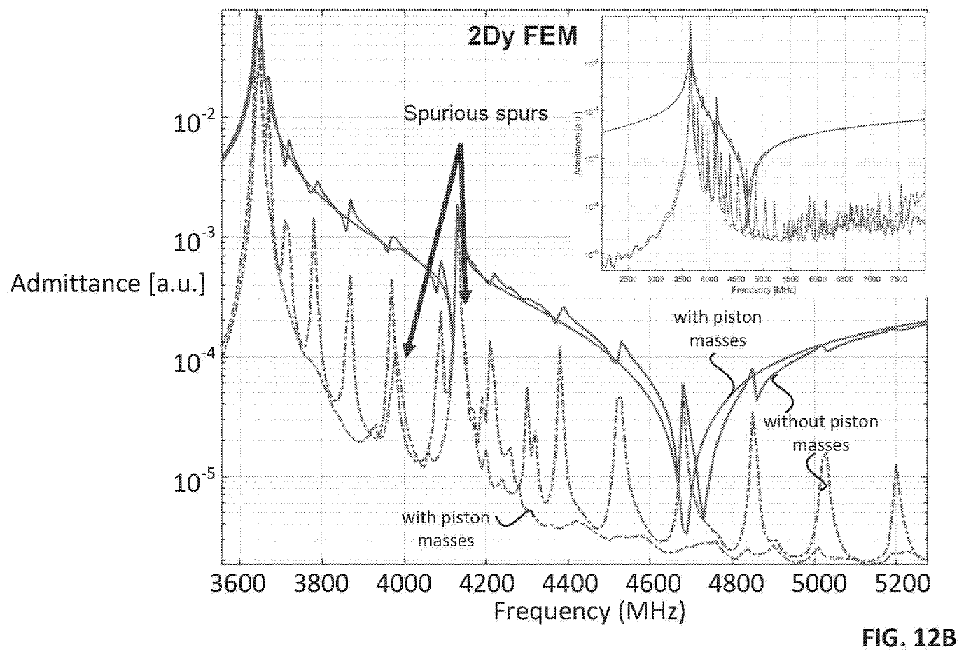

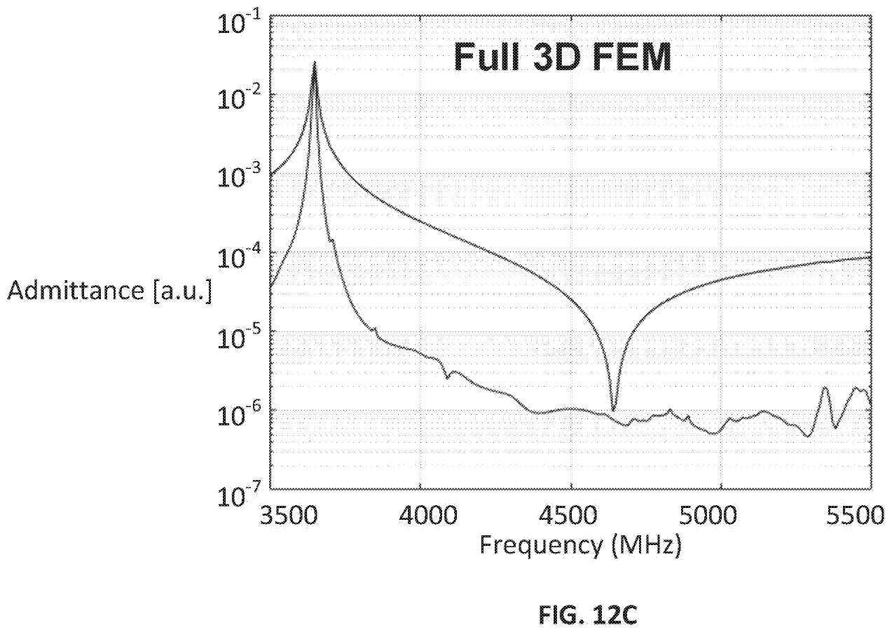

FIG. 12A illustrates a cross-sectional view of an IDT finger (e.g., an acoustically resonant nanowire) of an acoustic resonator configuration as shown in FIG. 8 according to an exemplary aspect. It is noted that the first cross-sectional view in the XZ plane that is shown in FIG. 12A generally corresponds to the configuration described above with respect to FIG. 10 and the details will not be repeated herein. Moreover, the second cross-sectional view in the ZY plane that is shown in FIG. 12A can correspond to the same configuration and includes the plurality of pistons as described above with respect to FIG. 8. In this case, the piston can have an exemplary height of 120 nm.

FIGS. 12B and 12C illustrate graphs of an admittance [y] as a function of frequency of an acoustic resonator according to an exemplary aspect. As described above with respect to FIG. 8, the transverse (i.e., the Y-direction) modes can be substantially and/or completely suppressed with piston masses. FIG. 12B illustrates a 2Dy FEM simulation for the acoustic resonator structure without the piston masses, which illustrates the aperture-dependent transverse modes. The 2Dy FEM for the same acoustic resonator structure with piston masses added on top and bottom as described above with respect to FIG. 8 is also shown in which the transverse modes are shown to be completely suppressed. FIG. 12C illustrates a simulation in full 3D FEM for the same acoustic resonator structure with piston masses, which also confirms the transverse mode suppression.

In yet another exemplary aspect, a multi-layer electrode may be used for vertical field excited resonators (e.g., YBAR, McBAW, ARN, and the like).

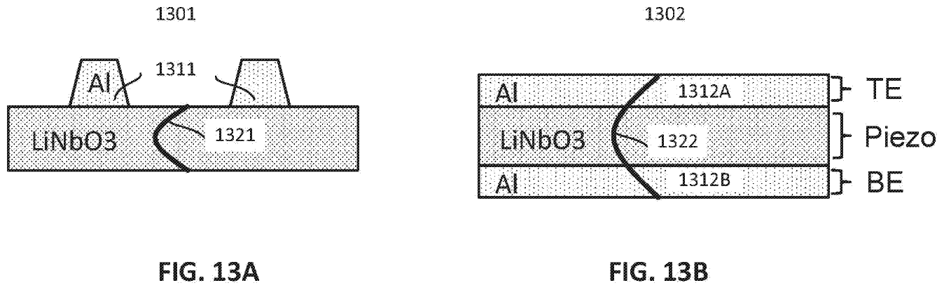

Specifically, FIGS. 13A-13B depict stress field in laterally and vertically excited devices. In some examples, such as shown in FIG. 13B, for a vertically excited structure 1302 such as ARN, YBAR, and McBAW, the electrodes lie along an acoustic path (e.g., Al) 1312A-1312B, as indicated by stress field 1322, significant acoustic energy/stress in the metal can lead to significant acoustic loss in the electrodes. For a laterally excited device 1301, such as an XBAR, shown in FIG. 13A, the stress field 1321, the metal doesn't lie along the acoustic path, the acoustic energy/stress is primarily confined to region between metal IDT (e.g., Al) 1311, as such acoustic energy/stress in the metal is less and acoustic loss in the electrodes is minimal. To reduce (e.g., minimize) energy/acoustic damping in the electrode (e.g., the metal layer) for vertically excited structures, electrode materials with a higher Q factor may be used, the energy distribution within the electrode may be reduced (e.g., minimized), and an electrode thickness may be reduced.

According to an exemplary aspect of the disclosure, a multi-layer metal structure including multiple layers of electrodes along a thickness direction (e.g., the Z axis) may be used as a vertically excited structure. Examples of the vertically excited structure include an acoustic resonator structure such as shown in FIGS. 1, 2, 4A-B, 5, 8, and the like.

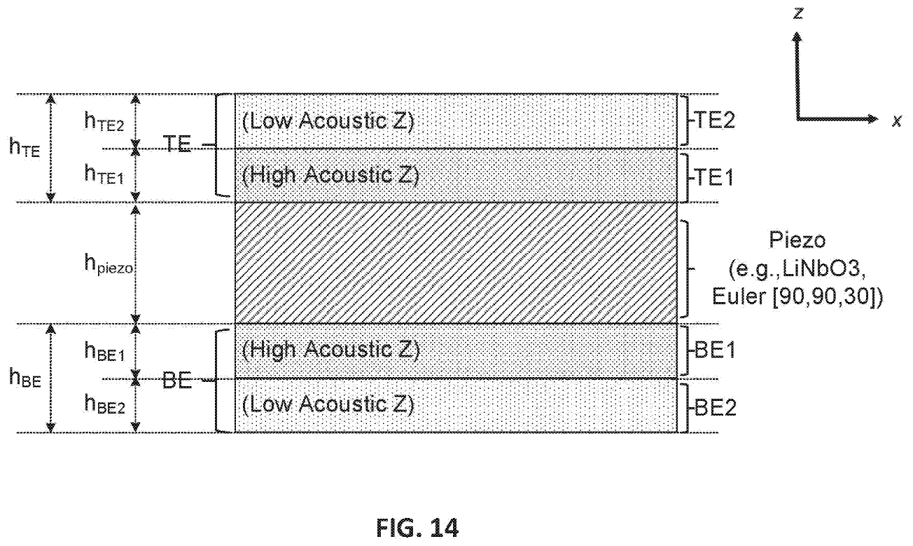

FIG. 14 shows an example of a multi-layer metal structure (or a multi-layer electrode) for a first conductor pattern (TE) disposed on a first surface of the piezoelectric layer (Piezo) and for a second conductor pattern (BE) disposed on a second surface of the piezoelectric layer of an acoustic resonator structure according to an aspect of the disclosure. It should be appreciated that the structure shown in FIG. 14 can generally correspond to that shown in FIG. 13B, except that the first conductor pattern (TE) may include a first electrode layer (TE1) having a first acoustic impedance (e.g., a high acoustic Z) and a second electrode layer (TE2) having a second acoustic impedance (e.g., a low acoustic Z) that is lower than the first acoustic impedance. The second conductor pattern (BE) may include a first electrode layer (BE1) having a first acoustic impedance (e.g., a high acoustic Z) and a second electrode layer (BE2) having a second acoustic impedance (e.g., a low acoustic Z) that is lower than the first acoustic impedance.

In an example, the multi-layer metal structure is symmetric, for example, a thickness (or a height) along the Z axis of TE1 is substantially identical to a thickness (or a height) along the Z axis of BE1. Similarly, a thickness (or a height) along the Z axis of TE2 is substantially identical to a thickness (or a height) along the Z axis of BE2. In addition, materials of TE1 and BE1 are substantially identical, and materials of TE2 and BE2 are substantially identical.

In some examples, the multi-layer metal structure is asymmetric.

In an example, such as shown in FIG. 14, a number of the multiple layers of electrodes of the first conductor pattern is two, and a number of the multiple layers of electrodes of the second conductor pattern is two, and thus the multiple layers of electrodes is referred to as a 2-layer electrode or a 2-layer electrode structure.

In an example, such as shown in FIG. 14, the first electrode layer (TE1) of the first conductor pattern is disposed between the second electrode layer (TE2) of the first conductor pattern and the piezoelectric layer (e.g., made from lithium niobate (LiNbO₃) or a similar synthetic salt formed from niobium, lithium, and oxygen), and the first electrode layer (BE1) of the second conductor pattern is disposed between the second electrode layer (BE2) of the second conductor pattern and the piezoelectric layer.

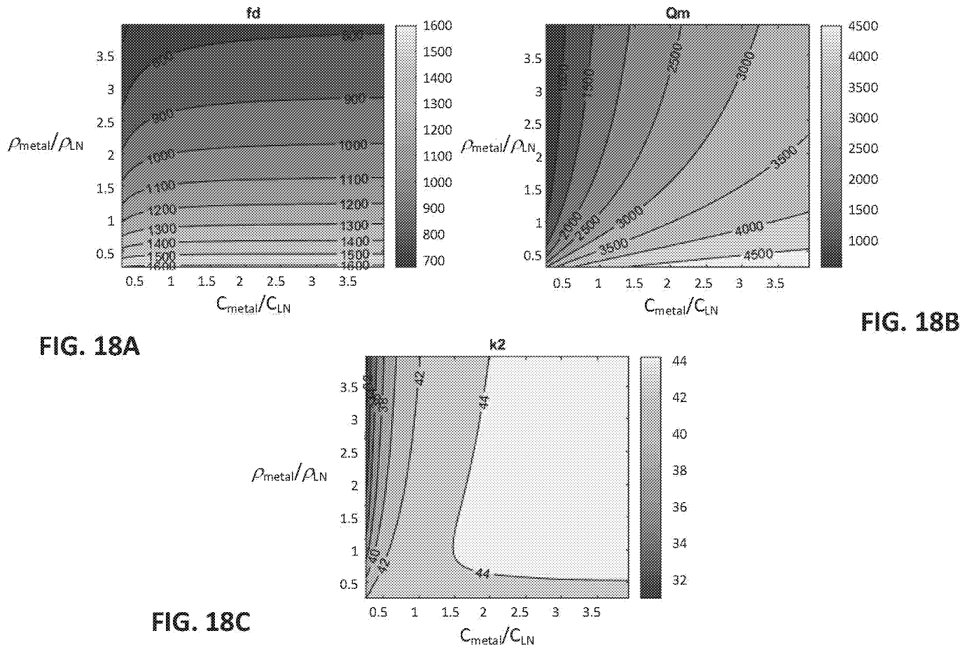

Referring to FIG. 14, the 2-layer electrode where the thin high impedance metal TE1 or BE1 (e.g., tungsten (W), platinum (Pt), molybdenum (Mo), ruthenium (Ru), or the like) is placed closest to the piezoelectric layer (e.g., directly on the piezoelectric layer) followed by the low impedance metal (e.g., Al) TE2 or BE2 may be used, for example, to reduce (e.g., significantly reduce) energy and loss within the electrode layer(s) (e.g., TE and/or BE). Further, in some examples, benefits include a higher electromechanical coupling (e.g., a k² improvement) and a reduction in trace resistance of the IDT. In contrast, a single-layer electrode using a high velocity material to reduce (e.g., minimize) energy and loss within the single-layer electrode is not as effective as the 2-layer electrode described in the disclosure. The high velocity material is described below with reference to FIGS. 18A-18C. In some examples, the high velocity material refers to a material that is relatively stiff and has a relatively small density.

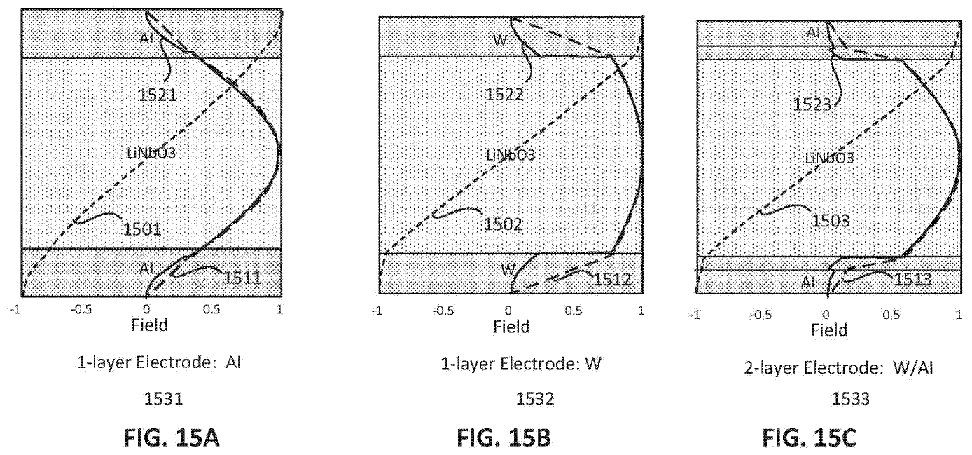

FIGS. 15A-15C show displacements 1501, 1502 and 1503, stresses 1511, 1512 and 1513, and acoustic energies 1521, 1522 and 1523 of three different electrode structures 1531, 1532 and 1533, respectively. The electrode structure 1531 is a 1-layer electrode including Al (e.g., both TE1 and TE2 are made of Al). The electrode structure 1532 is a 1-layer electrode including W. The electrode structure 1533 is a 2-layer electrode including W as TE1 and Al as TE2. FIGS. 15A-15C show that using the 2-layer electrode structure 1533 where a thin high impedance metal (e.g., W, Pt, Mo, or the like) is placed closest to the piezoelectric layer followed by a low impedance metal (e.g., Al) can significantly reduce energy within the electrode structure 1533 (W and Al). Referring to FIGS. 15A-15C, the distribution of the energy 1523 within the metal (Al and W) in FIG. 15C is less than the distributions of the energies 1521 and 1522 within the metal (Al or W) of a single layer electrode in FIGS. 15A and 15B.

The multi-layer electrode structure such as the 2-layer electrode structure shown in FIG. 14 may be optimized, for example, by manipulating the geometry and/or the materials of the multi-layer electrode structure. In an aspect, the optimization may be determined using certain parameters (e.g., fd, Qm, k2, and/or the like) indicating performances of the multi-layer electrode structure. Manipulating the geometry of the multi-layer electrode structure may include controlling thicknesses of TE1, TE2, TE, BE1, BE2, BE, and/or the piezoelectric layer. In an aspect, the multi-layer electrode structure such as the 2-layer electrode structure shown in FIG. 14 may be optimized, for example, by controlling a ratio (indicated by h_{TE}/h_{piezo}) of a thickness of TE h_{TE} over a thickness of the piezoelectric layer h_{piezo}, a ratio (indicated by h_{TE1}/h_{TE}) of a thickness of TE1 h_{TE1} over the thickness of TE h_{TE}, a ratio (indicated by h_{BE}/h_{piezo}) of a thickness of BE h_{BE} over the thickness of the piezoelectric layer, a ratio (indicated by h_{BE1}/h_{BE}) of a thickness of BE1 h_{BE1} over the thickness of BE, and/or the like.

In an aspect, for the optimal electrode stack, parameters that characterize the acoustic resonator including a parameter fd, a quality factor (Qm), and an electromechanical coupling (k2) may be relatively large. An electrode stack (or a multi-layer electrode) may be optimized by determining the optimal ratio h_{TE}/h_{piezo} and the optimal ratio h_{TE1}/h_{TE} based on a parameter fd plot, a quality factor or Q-factor (Qm) plot, and/or an electromechanical coupling (k2) plot. In an example, fd is the frequency constant in m/s, that is the frequency times by the thickness of the piezoelectric layer h_{piezo}. In an example, Qm is a motional Q-factor at resonance. In some examples, the 2-layer electrode are optimized to achieve relatively large fd, Qm, and/or k2.

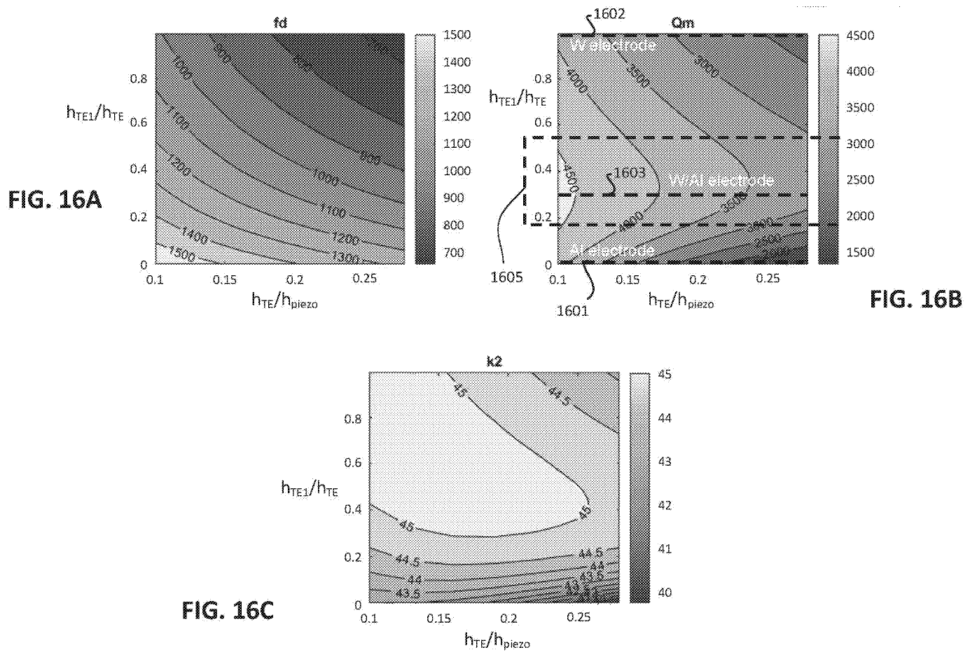

FIGS. 16A-16C show an fd plot, a Qm plot, and a k2 plot, respectively, for an acoustic resonator, such as an ARN, that has a 2-layer electrode structure shown in FIG. 14 according to an aspect of the disclosure. For the example shown in FIGS. 16A-16C, layers TE1 and BE1 are formed with W, and layers TE2 and BE2 are formed with Al. Layer TE includes TE1 and TE2 and layer BE includes BE1 and BE2. The piezoelectric layer (e.g., having Euler angles of (90, 90, 30) and made of LiNbO₃) is disposed between TE and BE. The quality factor Q_{piezo} of the piezoelectric layer is 5000. The quality factor Qₘₑₜₐₗ of the metal layer is 200. For each plot, the x-axis (the horizontal axis) indicates a ratio h_{TE}/h_{piezo} of the thickness of the electrode to the piezo thickness, and the y-axis (the vertical axis) indicates a ratio h_{TE1}/h_{TE} of the thickness of the first electrode layer W to the total thickness of the 2-layer electrode.

Referring to FIG. 16B, a dashed line 1601 indicates that the 2-layer electrode is substantially identical to a single-layer electrode made of TE2 (which can be aluminum) since the ratio h_{TE1}/h_{TE} approaches 0. A dashed line 1602 indicates that the 2-layer electrode is substantially identical to a single-layer electrode made of TE1 (which is W) since the ratio h_{TE1}/h_{TE} approaches 1. A dashed line 1603, within the dashed area 1605, indicates that the 2-layer electrode is a composite electrode including the first electrode layer W and the second electrode layer Al since the ratio h_{TE1}/h_{TE} is between 0 and 1. The dashed area 1605 indicates a range of acceptable ratios of h_{TE1}/h_{TE} from roughly greater than 0.1 and less than 0.6. FIG. 16B shows that the quality factor (Qm) increases when the ratio h_{TE1}/h_{TE} increases from 0 to an optimal ratio and when the ratio h_{TE1}/h_{TE} decreases from 1 to the optimal ratio, and thus using the 2-layer electrode may improve Qm. In the example shown in FIG. 16B, the optimal ratio is in a range, such as between 0.2 to 0.5 (e.g., 0.3 to 0.4). FIGS. 16A-16C show that a 2-layer electrode may improve Qm and k2 when compared with a single-layer electrode made of Al or W.

The range where the optimal ratio (e.g., the optimal ratio for h_{TE1}/h_{TE}) occurs may depend on which one or more parameters are used to optimize the ratio, e.g., whether the Qm is used (as shown in FIG. 16B), whether the fd is used (as shown in FIG. 16A), and/or whether the k² is used (as shown in FIG. 16C). In an example, the Qm is used (as shown in FIG. 16B) to optimize the range where the optimal ratio (e.g., the optimal ratio for h_{TE1}/h_{TE}) occurs.

Referring to FIGS. 16A-16B, when h_{TE1}/h_{TE} increases indicating using more of the first electrode layer, in an example, Qm increases and fd decreases. Thus, a trade-off may occur when optimizing the ratio for multiple parameters.

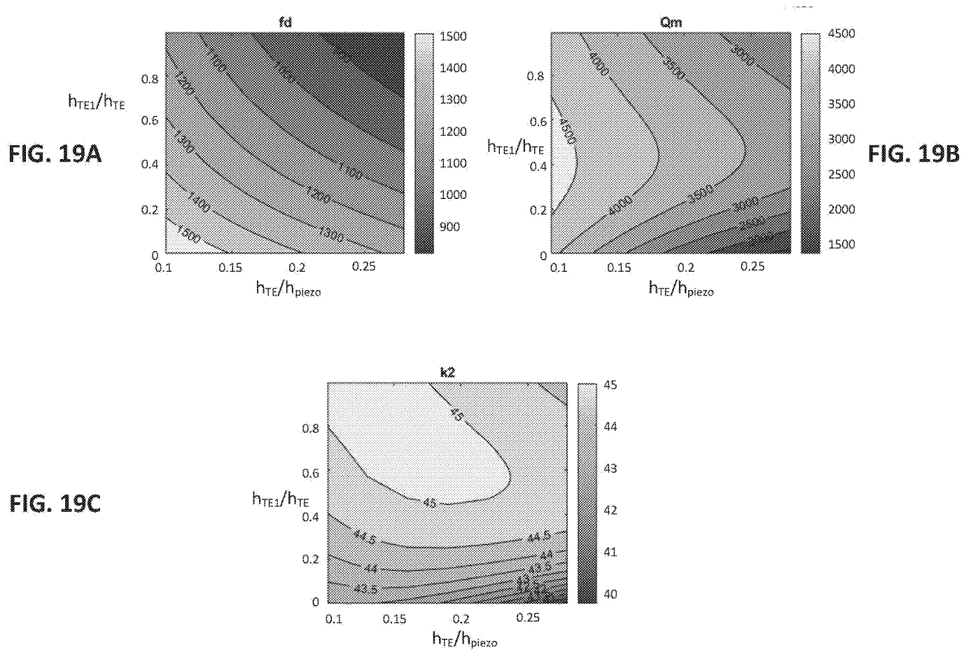

The range where the optimal ratio (e.g., the optimal ratio for h_{TE1}/h_{TE}) occurs may depend on the materials of the first electrode layer (TE1 and/or BE1) and/or the second electrode layer (TE2 and/or BE2), as shown in FIGS. 19A-19C, FIGS. 20A-20C, and FIGS. 21A-21C.

In an aspect, the ratio h_{TE1}/h_{TE} of the height (or the thickness) of TE1 over the total thickness (or the total height) of the multiple layers of electrodes (TE) may be from 0.1 to 0.6. In an exemplary aspect, the ratio h_{BE1}/h_{BE} of the height (or the thickness) of BE1 over the total thickness (or the total height) of the multiple layers of electrodes (BE) may be from 0.1 to 0.6. In an aspect, the ratio h_{TE}/h_{piezo} of the total thickness of TE over the thickness of the piezoelectric layer may be from 0.1 to 0.5. In an aspect, the ratio h_{BE}/h_{piezo} of the total thickness of BE over the thickness of the piezoelectric layer may be from 0.1 to 0.5. The ratios may be determined based on graphs illustrating simulated results in FIGS. 19A-19C, FIGS. 20A-20C, and FIGS. 21A-21C.

With a proper electrode ratio as described above, acoustic energy in the 2-layer metal (e.g., TE and/or BE) may be reduced (e.g., minimized) to reduce attenuation in lossy metal layers to improve the Q-factor and may increase coupling (e.g., a separation between the resonant frequency Fr and the anti-resonant frequency Fa). Moreover, in the exemplary aspect, TE and BE are made to be symmetric.

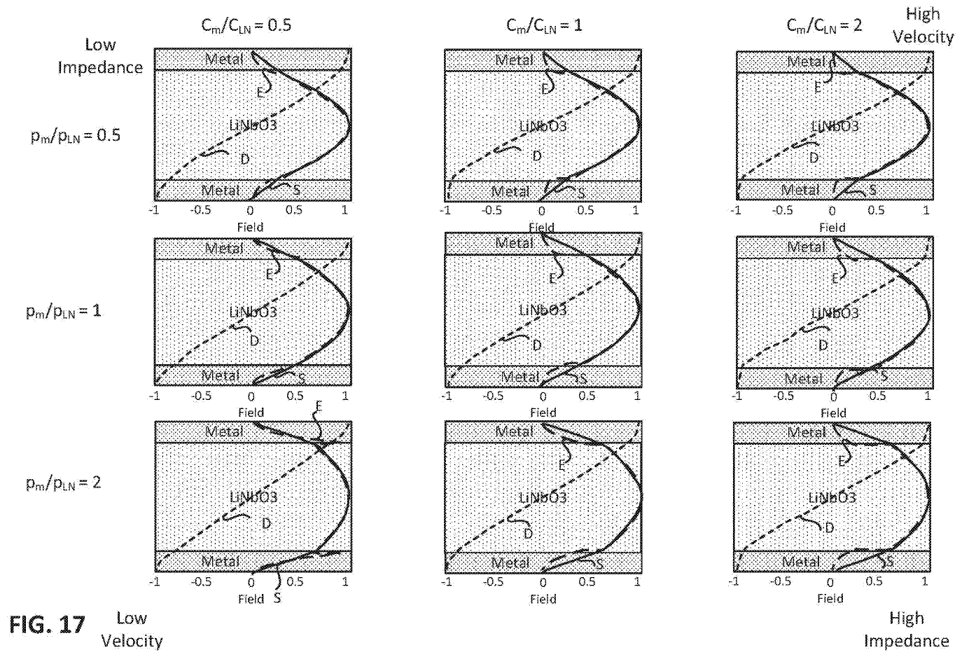

FIG. 17 shows simulated results of displacements (“D”), stresses (“S”), and energies (“E”) of nine electrode structures, respectively. Each of the nine electrode structures has a 1-layer electrode. The three columns correspond to three different values (0.5, 1, and 2) of a stiffness ratio Cₘ/C_{LN}, Cₘ is the stiffness or elastic constant of the metal layer and C_{LN} is the stiffness or elastic constant of the piezoelectric layer. Accordingly, the electrode becomes stiffer from the left side to the right side. The three rows correspond to three different values (0.5, 1, and 2) of a density ratio ρₘ/ρ_{LN} of a density of the electrode ρₘ over a density of the piezoelectric layer ρ_{LN}. Accordingly, the electrode becomes heavier per unit volume from the top row to the bottom row.

FIG. 17 shows that energy (E) and therefore acoustic damping in the electrode may be reduced (e.g., minimized) by choosing a light (e.g., having a low ρₘ/ρ_{LN}) and stiff metal (e.g., having a high Cₘ/C_{LN}) which may be referred to as a high velocity metal that is located at a top-right corner in FIGS. 18A to 18C. In this example, the light and stiff metal (e.g., the high velocity metal) has a Cₘ/C_{LN} of 2 and a ρₘ/ρ_{LN} of 0.5.

FIGS. 18A-18C show examples of optimal material parameters such as stiffness and density as indicated by Cₘ/C_{LN} and ρₘ/ρ_{LN}, respectively for the single electrode according to an aspect of the disclosure. The ratio h_{TE}/h_{piezo} is 0.2, and the ratio h_{BE}/h_{piezo} is 0.2 in the simulations used for FIGS. 18A-18C. FIG. 18A shows an fd plot indicating how the parameter fd varies with Cₘ/C_{LN} and ρₘ/ρ_{LN}. FIG. 18B shows a Qm plot indicating how the parameter Qm varies with Cₘ/C_{LN} and ρₘ/ρ_{LN}. FIG. 18B shows that a higher Qm (e.g., a maximal Qm) may be obtained by using a metal (e.g., the high velocity metal) with a high stiffness and a small density, which is also shown in FIG. 17. FIG. 18C shows a k2 plot indicating how the parameter k2 varies with Cₘ/C_{LN} and ρₘ/ρ_{LN}. FIG. 18C shows that a higher k2 (e.g., a maximal k2) may be obtained by using a metal (e.g., also referred to as a high impedance metal) with a high stiffness and a high density, which is also shown at the bottom-right corner in FIG. 17 (with a Cₘ/C_{LN} of 2 and a ρₘ/ρ_{LN} of 2 in FIG. 17).

Referring back to FIG. 17, when Cₘ/C_{LN} is low (e.g., 0.5) and ρₘ/ρ_{LN} is high (e.g., 2), the metal may be referred to as a low velocity metal, and may result in a relatively large energy dissipation (e.g., the maximal energy) in the metal, which may not be optimal for many applications.

As described above, the 2-layer electrode may be optimized by manipulating the geometry of the 2-layer electrode (e.g., described in FIGS. 16A-16C) and by using different metal materials (e.g., described in FIGS. 17 and 18A-18C) in the 1-layer electrode.

In an example, different metal materials are used for TE1 and BE1 in the 2-layer electrode. FIGS. 19A-19C, 20A-20C, and 21A-21C show the effect of different metal materials as TE1 and BE1 in the 2-layer electrode.

FIGS. 19A-19C show an fd plot, a Qm plot, and a k2 plot, respectively, for a vertically excited structure that has a 2-layer electrode structure shown in FIG. 14 according to an aspect of the disclosure. In the example shown in FIGS. 19A-19C, TE1 and BE1 are formed with Ru, TE2 and BE2 are formed with Al. TE includes TE1 and TE2. BE includes BE1 and BE2. The piezoelectric layer is disposed between TE and BE with Euler angles [90°, 90°, 30°] and is made of lithium niobate (e.g., LiNbO₃). The quality factor Q_{piezo} of the piezoelectric layer is 5000. The quality factor Qₘₑₜₐₗ of the metal layer is 200. For each plot, the x-axis (the horizontal axis) indicates a ratio h_{TE}/h_{piezo} of the thickness of the electrode to the piezo thickness, and the y-axis (the vertical axis) indicates a ratio h_{TE1}/h_{TE} of the thickness of the first electrode layer Ru to the total thickness of the 2-layer electrode. FIGS. 19A-19C show that a 2-layer electrode may improve Qm and k2 when compared with a single-layer electrode made of Ru or W.

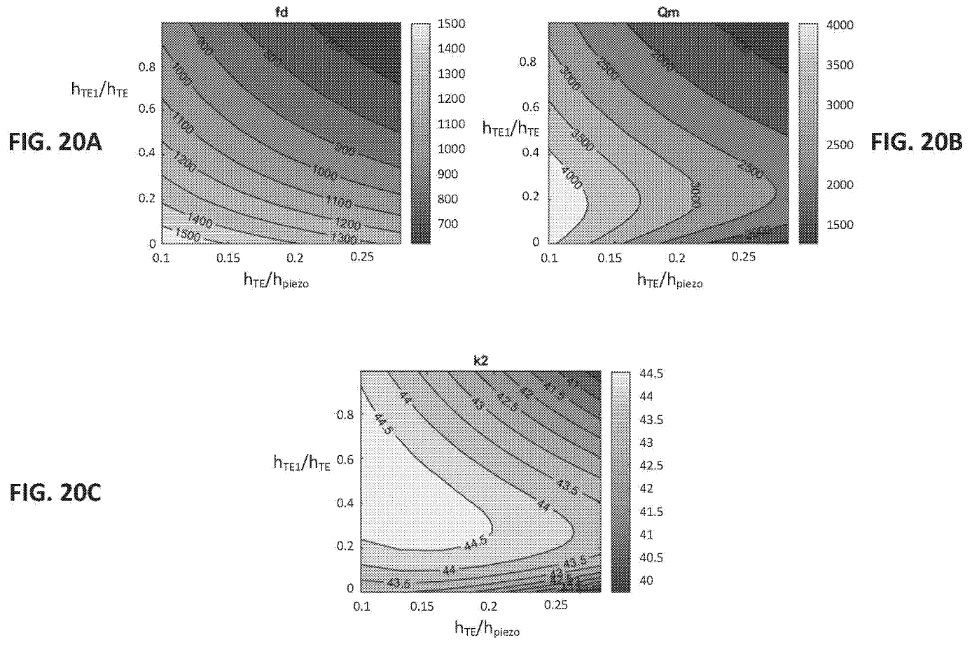

FIGS. 20A-20C show an fd plot, a Qm plot, and a k2 plot, respectively, for a vertically excited structure that has a 2-layer electrode structure shown in FIG. 14 according to an aspect of the disclosure. In the example shown in FIGS. 20A-20C, TE1 and BE1 are formed with Pt, TE2 and BE2 are formed with Al. TE includes TE1 and TE2. BE includes BE1 and BE2. The piezoelectric layer is disposed between TE and BE with Euler angles [90°, 90°, 30°] and is made of lithium niobate (LiNbO₃). The quality factor Q_{piezo} of the piezoelectric layer is 5000. The quality factor Qₘₑₜₐₗ of the metal layer is 200. For each plot, the x-axis (the horizontal axis) indicates a ratio h_{TE}/h_{piezo} of the thickness of the electrode to the piezo thickness, and the y-axis (the vertical axis) indicates a ratio h_{TE1}/h_{TE} of the thickness of the first electrode layer Pt to the total thickness of the 2-layer electrode. FIGS. 20A-20C show that a 2-layer electrode may improve Qm and k2 when compared with a single-layer electrode made of Pt or W. In an example, the 2-layer electrode may be used in a McBAW resonator.

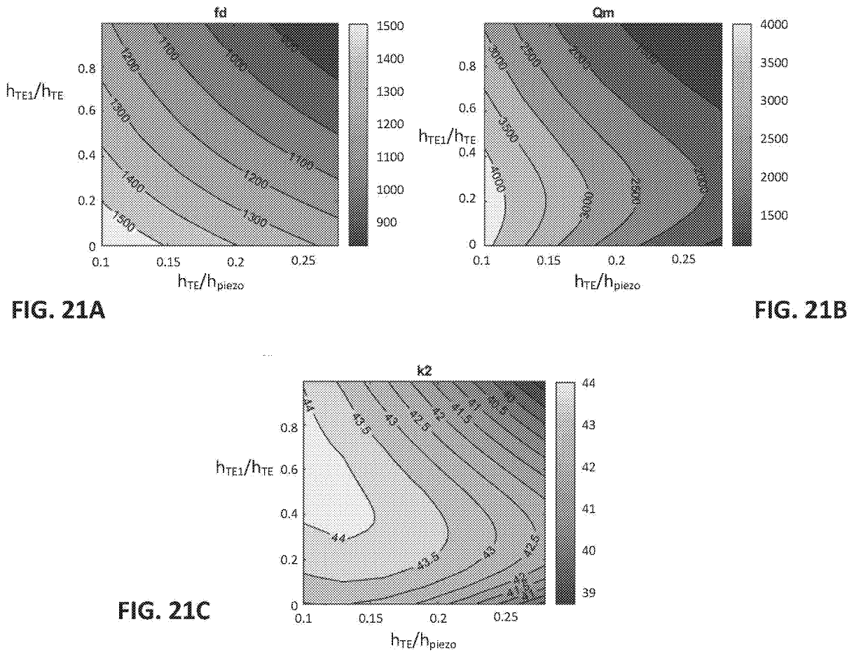

FIGS. 21A-21C show an fd plot, a Qm plot, and a k2 plot, respectively, for a vertically excited structure that has a 2-layer electrode structure shown in FIG. 14 according to an aspect of the disclosure. In the example shown in FIGS. 21A-21C, TE1 and BE1 are formed with Mo, TE2 and BE2 are formed with Al. TE includes TE1 and TE2. BE includes BE1 and BE2. The piezoelectric layer is disposed between TE and BE with Euler angles [90°, 90°, 30°] and is made of lithium niobate (LiNbO₃). The quality factor Q_{piezo} of the piezoelectric layer is 5000. The quality factor Qₘₑₜₐₗ of the metal layer is 200. For each plot, the x-axis (the horizontal axis) indicates a ratio h_{TE}/h_{piezo} of the thickness of the electrode to the piezo thickness, and the y-axis (the vertical axis) indicates a ratio h_{TE1}/h_{TE} of the thickness of the first electrode layer Mo to the total thickness of the 2-layer electrode.

Comparing FIGS. 16B, 19B, 20B and 21B, the optimal range for the ratios h_{TE}/h_{piezo} and h_{TE1}/h_{TE} may depend on the materials in the 2-layer electrode. FIG. 16B indicates that to achieve a relatively large Qm when TE1 and BE1 include W, the optimal range for the ratio h_{TE1}/h_{TE} is approximately from 0.2 to 0.5 (e.g., from 0.3 to 0.4). FIG. 19B indicates that to achieve a relatively large Qm when TE1 and BE1 include Ru, the optimal range for the ratio h_{TE1}/h_{TE} is approximately 0.3 to 0.6 (e.g., 0.4 to 0.6). FIGS. 20B and 21B indicate that to achieve a relatively large Qm when TE1 and BE1 include Pt or Mo, the optimal range for the ratio h_{TE1}/h_{TE} is approximately 0.1 to 0.3 (e.g., 0.18 to 0.25). As TE1 is changed from (i) W or Ru to (ii) Pt or Mo, the thickness of TE1 is to be reduced in order to obtain a larger Qm.

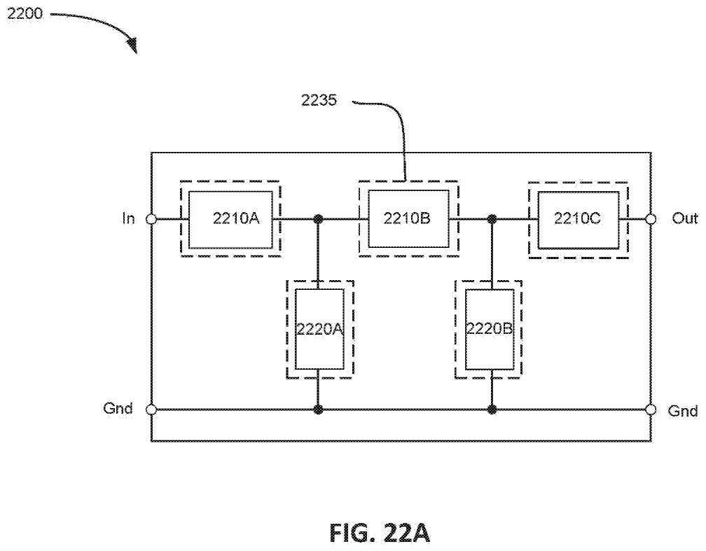

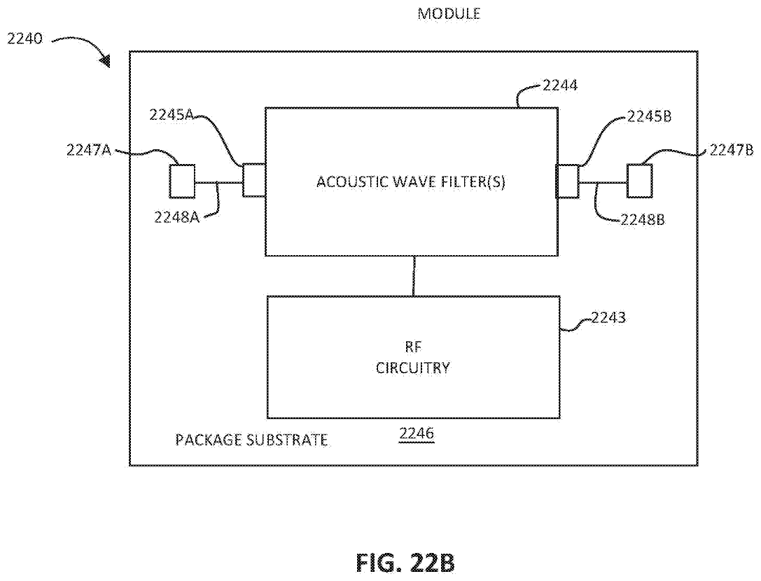

FIG. 22A is a schematic block diagram of a bandpass filter using the acoustic resonator structure according to an exemplary aspect. The bandpass filter 2200 has a conventional ladder filter architecture including three series resonators 2210A, 2210B, and 2210C and two shunt resonators 2220A and 2220B. The series resonators 2210A, 2210B, and 2210C are connected in series between a first port and a second port (hence the term “series resonator”). In FIG. 22A, the first and second ports are labeled “In” and “Out”, respectively. However, the filter 2200 is bidirectional and either port may serve as the input or output of the filter. At least two shunt resonators, such as the shunt resonators 2220A and 2220B, are connected from nodes between series resonators to a ground connection. A filter may contain additional reactive components, such as inductors, not shown in FIG. 22A. All the shunt resonators and series resonators are acoustic resonators in the exemplary aspect. The inclusion of three series and two shunt resonators is an example. A filter may have more or fewer than five total resonators, more or fewer than three series resonators, and more or fewer than two shunt resonators. Typically, all of the series resonators are connected in series between an input and an output of the filter. All of the shunt resonators are typically connected between ground and the input, the output, or a node between two series resonators.

In the exemplary filter 2200, the series resonators 2210A, 2210B, and 2210C and the shunt resonators 2220A and 2220B of the filter 2200 are formed on at least one, and in some cases a single, piezoelectric layer of piezoelectric material bonded to a silicon substrate (not visible). However, in alternative aspects, the individual resonators may each be formed on a separate piezoelectric layer bonded to a separate substrate, for example. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 22A, the cavities are illustrated schematically as the dashed rectangles (such as the rectangle 2235). In this example, each IDT is disposed over a respective cavity. In other filters, the IDTs of two or more resonators may be disposed over a single cavity.

Each of the resonators in the filter 2200 has a resonance where the admittance of the resonator is very high and an anti-resonance where the admittance of the resonator is very low. The resonance and anti-resonance occur at a resonance frequency and an anti-resonance frequency, respectively, which may be the same or different for the various resonators in the filter 2200. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 2200, each of the resonators may have a particular coupling parameter to which the respective resonator is tuned in order to achieve the required frequency response of the filter 2200. According to an exemplary aspect, each of the series resonators 2210A, 2210B, and 2210C and the shunt resonators 2220A and 2220B can have an acoustic resonator configuration as described above with respect to FIGS. 1-2, 4A, 4B, 5, 6 and 8.

FIG. 22B is a schematic diagram of a radio frequency module that includes an acoustic wave filter of FIG. 22A according to an exemplary aspect. In particular, FIG. 22B illustrate a radio frequency module 2240 that includes one or more acoustic wave filters 2244 according to an exemplary aspect. The illustrated radio frequency module 2240 also includes radio frequency (RF) circuitry (or circuit) 2243. In an exemplary aspect, the acoustic wave filters 2244 may include one or more of filter 2200, as described above with respect to FIG. 22A.

The acoustic wave filter 2244 shown in FIG. 22B includes terminals 2245A and 2245B (e.g., first and second terminals). The terminals 2245A and 2245B can serve, for example, as an input contact and an output contact for the acoustic wave filter 2244. Although two terminals are illustrated, any suitable number of terminals can be implemented for a particular application. The acoustic wave filter 2244 and the RF circuitry 2243 are on a package substrate 2246 (e.g., a common substrate) in FIG. 22B. The package substrate 2246 can be a laminate substrate. The terminals 2245A and 2245B can be electrically connected to contacts 2247A and 2247B, respectively, on the package substrate 2246 by way of electrical connectors 2248A and 2248B, respectively. The electrical connectors 2248A and 2248B can be bumps or wire bonds, for example. In an exemplary aspect, the acoustic wave filter 2244 and the RF circuitry 2243 may be enclosed together within a common package, with or without using the package substrate 2246.

The RF circuitry 2243 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 2243 can be electrically connected to the one or more acoustic wave filters 2244. The radio frequency module 2240 can include one or more packaging structures to, for example, provide protection and/or facilitate easier handling of the radio frequency module 2240. Such a packaging structure can include an overmold structure formed over the package substrate 2246. The overmold structure can encapsulate some or all of the components of the radio frequency module 2240.

Referring back to FIGS. 4A-4B, the electrodes 436A and 436B are applied with different electric potentials (e.g., electric potentials with different polarities being applied on the electrodes 436A and 436B) during operation of a filter device that includes the exemplary resonator. For example, the electric potential applied on the electrode 436A is higher than the electric potential applied on the electrode 436B (e.g., as shown by positive sign at the electrode 436A and negative sign at the electrode 436B), with the electrical field in the ARNs being in the vertical direction (e.g., Z direction). Some exemplary aspects of the present disclosure also provide ARNs with electrical field excited in the laterally direction (e.g., perpendicular to the Z direction, in a direction parallel to the X-Y plane, such as in X direction, in Y direction, and the like).

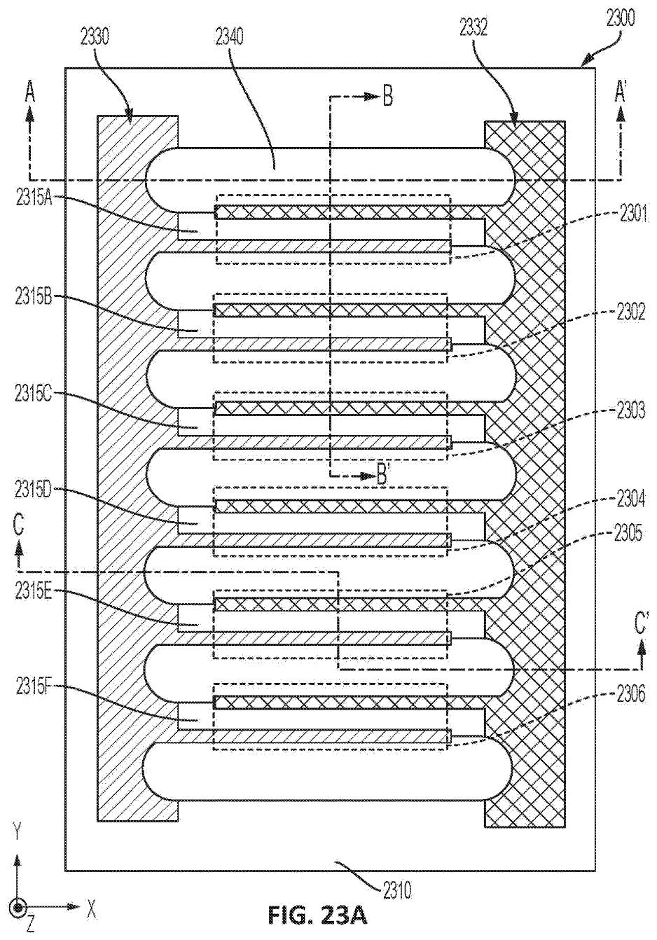

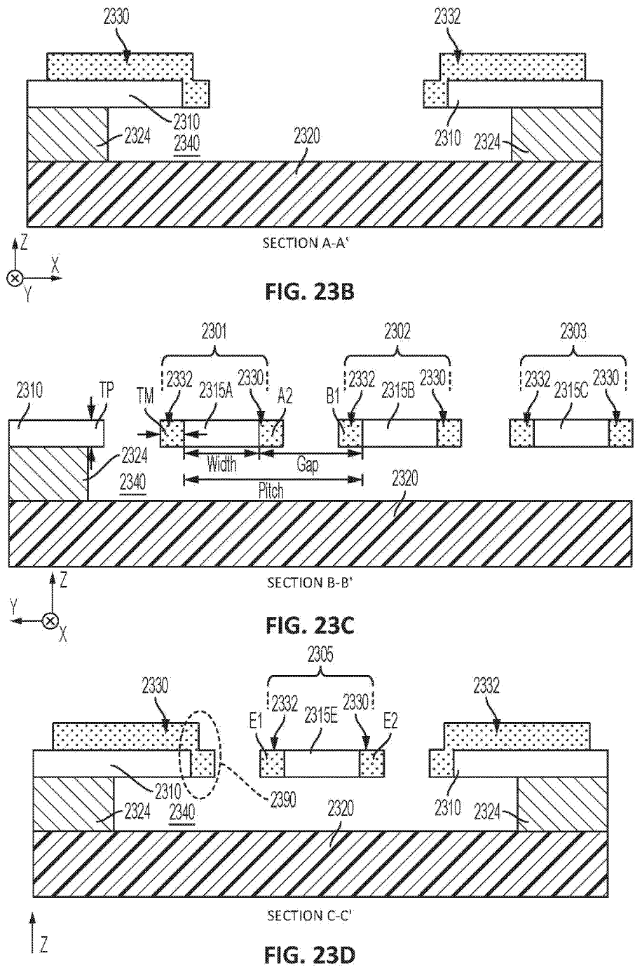

FIG. 23A shows a plan view of an acoustic resonator structure 2300 and FIGS. 23B-23D show different cross-sectional views of the acoustic resonator structure 2300 along different sectional lines (also referred to as cut lines) according to some exemplary aspects of the disclosure. FIG. 23B shows a cross-sectional view of the acoustic resonator structure 2300 along a section line A-A′ (e.g., cut line in X direction), FIG. 23C shows a cross-sectional view of the acoustic resonator structure 2300 along a section line B-B′ (e.g., a cut line in Y direction), and FIG. 23D shows a cross-sectional view of the acoustic resonator structure 2300 along a section line C-C′ (e.g., a cut line that turns from X direction to Y direction and back to X direction).

The acoustic resonator structure 2300 includes similar configurations as some acoustic resonator structures described above, such as the acoustic resonator structure in FIG. 1, the acoustic resonator structure in FIGS. 2A-2B, the acoustic resonator structure in FIGS. 4A-4B, and the acoustic resonator structure in FIG. 5. However, the acoustic resonator structure 2300 also includes different electrode configurations that configure the acoustic resonator structure 2300 to be laterally excited during operation.

As shown in FIGS. 23A-23D, the acoustic resonator structure 2300 is formed from a base substrate 2320, with the thickness direction of the substrate 2320 being in the Z direction. The substrate 2320 can provide mechanical support for the acoustic resonator structure 2300. The substrate 2320 may be, for example, silicon, sapphire, quartz, or some other material. In the example of FIGS. 23B-23D, one or more intermediate layers 2324 (e.g., dielectric layer, a silicon dioxide layer, and the like) are formed on the substrate 2320. The one or more intermediate layers 2324 are suitably patterned to form a cavity 2340 and define the boundaries of the cavity 2340. Further, a piezoelectric layer 2310 is supported the one or more intermediate layers 2324 in a similar configuration as described above with respect to FIG. 3B.

Also, the piezoelectric layer 2310 includes a plurality of piezoelectric bars (also referred to as released membranes, nanowires), such as shown by 2315A, 2315B, 2315C, 2315D, 2315E, and 2315F in FIG. 23A. Gaps are formed between neighboring piezoelectric bars, and each of the piezoelectric bars can vibrate in a lateral direction, such as in the ±Y direction. The piezoelectric bars 2315A to 2315F will extend full across the cavity as shown in in FIG. 23A with a conducive pattern disposed thereon to form respective electrodes. It should be appreciated that each of the plurality of piezoelectric bars 2315A to 2315F extend across the cavity 2340 in a first direction (e.g., the X-axis direction) that is perpendicular to the lateral direction, which can also be considered a second direction (e.g., the Y-axis direction). A thickness direction or a third direction is orthogonal to each of the first and second directions and can generally be considered the Z-axis direction in the exemplary aspect. The third direction is considered the thickness direction in that it is generally in the Z axis, which is in the thickness direction of substrate 2320, as shown in FIGS. 23B to 23D, for example. Thus, as also shown, the cavity 2340 generally extends in the thickness direction between the piezoelectric layer 2310 and the substrate 2320. Although not shown, one or more additional layers (e.g., dielectric layers) can be disposed on the substrate 2320 (e.g., in cavity 2340 and facing the piezoelectric layer 2310) and/or on the piezoelectric layer 2310 (e.g., in cavity 2340 and facing the substrate 2320).

Moreover, in the exemplary aspects of FIGS. 23A-23D, respective electrodes are formed on the sidewalls of the piezoelectric bars, such that the piezoelectric bars with the respective electrodes form separate ARN structures 2301, 2302, 2303, 2034, 2305, and 2306. For example, a first conductive pattern 2330 may include a first busbar and a second conductive pattern 2332 may include a second busbar that are formed from one or more metal layers, such as metal 1 layer (M1 layer) and can be applied with alternating, different electric potentials during operation.

Using the example shown in FIG. 23D, the ARN structure 2305 includes two electrodes E1 and E2 formed on two sidewalls of the piezoelectric bar 2315E, in which the two electrodes E1 and E2 are respectively connected to the busbars of the first conductive pattern 2330 and the second conductive pattern 2332, respectively. It should be appreciated that the two electrodes E1 and E are formed as part of the first conductive pattern 2330 and the second conductive pattern 2332, respectively, as would be appreciated to one skilled in the art. In an exemplary aspect, the two electrodes E1 and E2 are formed by suitably patterning the metal layer, with the electrode E1 being connected to the busbar of the first conductive pattern 2330, and the electrode E2 being is connected to the busbar of the second conductive pattern 2332. Thus, the two electrodes E1 and E2 sandwich the piezoelectric bar 2315E in a lateral direction that is orthogonal to the thickness direction of the substrate, the two electrodes E1 and E2 on the opposite sides of the piezoelectric bar 2315E are of opposite polarities.

It is noted that in the example of FIGS. 23A-23D, neighboring ARN structures in the ARN structures 2301-2306 have a gap in-between in the lateral direction, thus the piezoelectric bars can vibrate in the lateral direction according to the electric potentials applied on the electrodes. According to some exemplary aspects of the disclosure, the ARN structures 2301-2306 are configured to operate in the shear mode in which the particles in the piezoelectric bars move in the lateral direction parallel to the X-Y plane and perpendicular to the direction of wave propagation (e.g., in the vertical direction Z).

In some examples, the thickness of the metal layer (as shown by TM in FIG. 23C) and the thickness of the piezoelectric layer 2310 (as shown by TP in FIG. 23C) are suitably designed with an appropriate manufacturing process to enable the formation of the M1 fingers on the sidewalls of the piezoelectric bars as would be appreciated to one skilled in the art such that the fingers form the electrodes. In the exemplary aspect, the width of the metal layer TM is higher than the thickness TP of the piezoelectric layer 2310. In some examples, the piezoelectric bars can have about the same width. In some examples, the piezoelectric bars can be designed to have different widths. In some examples, the piezoelectric bars can have about the same gap width of gaps. In some examples, the piezoelectric bars can be designed to have different gap widths of gaps. In some examples, the piezoelectric bars can have about the same pitch width.

It is also noted that FIG. 23C, as an example, only show the metal layer forming the electrodes on the side of the piezoelectric layer. For example, ARN structure 2301 includes the piezoelectric bar 2315A with the first and second conductive patterns 2330 and 2332 forming the electrodes on the sides of the piezoelectric bar 2315A in the lateral or second direction. However, in an alternative aspect, the metal layer may be formed on one or both sidewalls of a piezoelectric bar (e.g., piezoelectric bar 2315A) of the nanowire structure 2301 and can also extend over the respective piezoelectric bar 2315A to partially overlap a top surface of the piezoelectric bar 2315A. An example of this configuration is shown in FIG. 23A, which is a plan view illustrating the electrodes partially overlapping the respective piezoelectric bars.

Moreover, in some exemplary aspects, the piezoelectric bars can be designed to have different pitch widths of pitches in a length direction, which is considered the lateral direction (i.e., the X-axis direction or second direction). According to an exemplary aspect of the disclosure, changes in the pitch widths across the ARN can be used for spur suppression as described above.

According to some exemplary aspects of the disclosure, placing electrodes on the lateral sides of the piezoelectric bar increases coupling and potentially reduces spurs as the electrical field does not curve from the opposite polarity of the neighboring fingers. Also according to some exemplary aspects of the disclosure, the cavity below the piezoelectric bar can help reduce loss and increase coupling comparing to some related structures with a pedestal supporting the piezoelectric bar.

According to some exemplary aspects of the disclosure, by suitably patterning the piezoelectric layer and the metal layer, the ARN structures can have different neighboring configurations. In the example of FIGS. 23A-23D, neighboring electrodes of the two neighboring ARN structures are configured to have the opposite polarities (i.e., reversing) as described above. For example as shown by FIG. 23C, the ARN structure 2301 and the ARN structure 2302 are neighboring ARN structures, the electrode A2 and the electrode B1 are neighboring electrodes of the two neighboring ARN structures 2301 and 2302, the electrode A2 and the electrode B1 are connected to different busbars, and thus are of opposite polarity.

According to an exemplary aspect of the disclosure, the busbars and the electrodes of the ARNs can be formed by the same metal layer (e.g., one of the first conductive pattern 2330 or the second conductive pattern 2332), the busbars are formed by the metal layer on the piezoelectric layer, and the metal layer can extend to the sidewalls of the gaps between piezoelectric bars to form the fingers, such as shown by 2390 in FIG. 23D. The electrode fingers on opposite sides of a piezoelectric bar of an ARN form the electrodes of the ARN as described above.

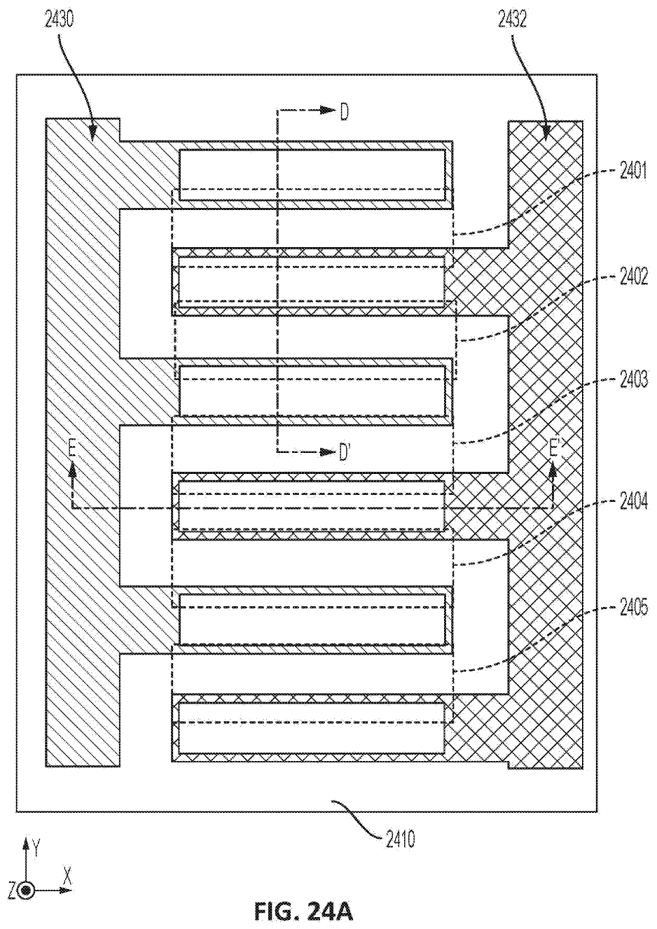

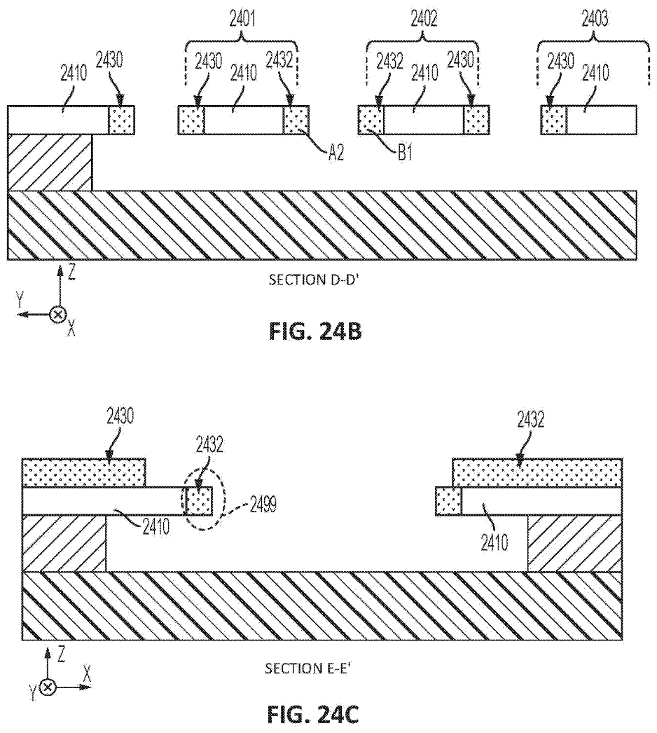

FIG. 24A shows a plan view of an acoustic resonator structure 2400 and FIGS. 24B-24C show cross-sectional views of the acoustic resonator structure 2400 along different section lines (also referred to as cut lines) according to some exemplary aspects of the disclosure. In particular, FIG. 24B shows a cross-sectional view of the acoustic resonator structure 2400 along a section line D-D′ (e.g., cut line in Y direction), FIG. 24C shows a cross-sectional view of the acoustic resonator structure 2400 along a section line E-E′ (e.g., a cut line in X direction).

It is noted that the acoustic resonator structure 2400 includes similar structures and configurations as the acoustic resonator structure 2300 described above, similar labels represent similar elements, the descriptions of the elements are omitted here for clarity. In particular, a first conductive pattern 2430 formed on piezoelectric layer 2410 corresponds to first conductive pattern 2330 and a second conductive pattern 2432 formed on piezoelectric layer 2410 corresponds to second conductive pattern 2332 as described above. As shown, each conductive pattern includes a respective busbar with electrodes extending of the piezoelectric bars. However, neighboring electrodes of the two neighboring ARN structures of the plurality of ARN structures 2401, 2402, 2403, 2404, to 2405 in the acoustic resonator structure 2400 are configured to have the same polarity. For example, an ARN structure 2401 and an ARN structure 2402 of the acoustic resonator structure 2400 are neighboring ARN structures, electrode A2 and the electrode B1 as shown in FIG. 24B are neighboring electrodes of the two neighboring ARN structures 2401 and 2402. For this configuration, the electrode A2 and the electrode B1 are connected to a same busbar of the busbar of the first conductive pattern 2432, and thus are of a same polarity.

Also, in the example of FIG. 24A-24C, the metal layer covers all the sidewalls of the gaps between neighboring ARN structures. It is noted that in some other examples, the metal layer can cover some sidewalls of the gaps between neighboring ARN structures, and leave some other sidewalls uncovered by the metal layer. According to an exemplary aspect of the disclosure, the metal layer can extend to the sidewalls of the gaps between piezoelectric bars to form the fingers, such as shown by 2499 in FIG. 24C. The electrode fingers on opposite sides of a piezoelectric bar of an ARN form the electrodes of the ARN as described above.

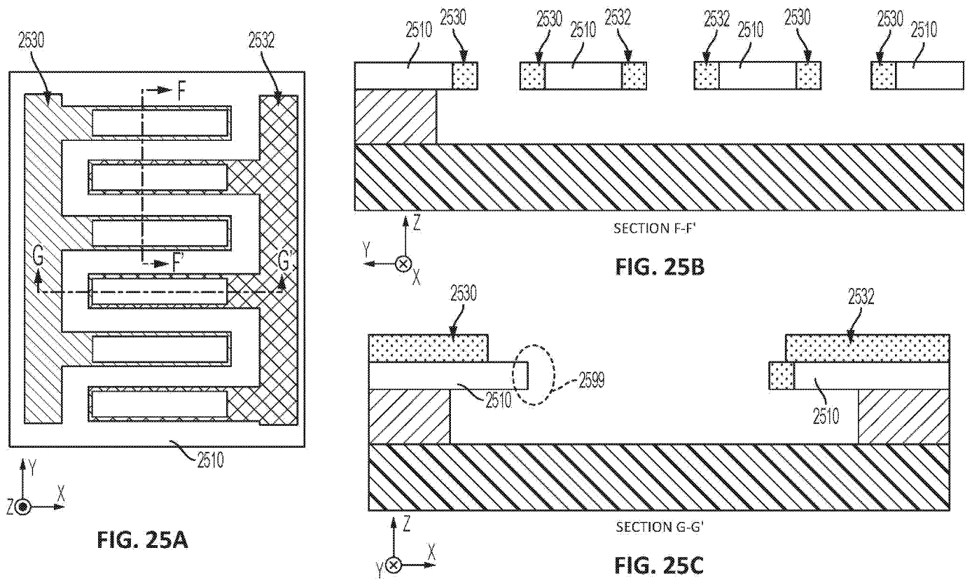

FIG. 25A shows a plan view of an acoustic resonator structure 2500 and FIGS. 25B-25C show cross-sectional views of the acoustic resonator structure 2500 along different section lines (also referred to as cut lines) according to some exemplary aspects of the disclosure. In particular, FIG. 25B shows a cross-sectional view of the acoustic resonator structure 2500 along a section line F-F′ (e.g., cut line in Y direction), and FIG. 25C shows a cross-sectional view of the acoustic resonator structure 2500 along a section line G-G′ (e.g., a cut line in X direction).

The acoustic resonator structure 2500 includes similar structures and configurations as the acoustic resonator structures 2300 and 2400 described above, similar labels represent similar elements, the descriptions of the elements are omitted here for clarity. In particular, a first conductive pattern 2530 formed on piezoelectric layer 2510 corresponds to first conductive pattern 2330 and a second conductive pattern 2532 formed on piezoelectric layer 2510 corresponds to second conductive pattern 2332 as described above. As shown, each conductive pattern includes a respective busbar with electrodes extending of the piezoelectric bars. However, in this embodiment, the metal layer can cover some sidewalls of the gaps between neighboring ARN structures, and leave some sidewalls uncovered by the M1 layer. For example, a sidewall portion 2599 is not covered with the metal layer in the example of FIGS. 25A-25C, and a corresponding sidewall portion 2499 is covered with the metal layer in the example of FIGS. 24A-24C as noted above.

According to some aspects of the disclosure, the metal layer on the sidewalls of the piezoelectric bars (e.g., to form the electrodes of the ARN structures), and the metal layer on the piezoelectric layer can be formed at the same time, or can be formed separately.

In a first exemplary manufacturing process, after the piezoelectric layer on the one or more intermediate layers is pattered to form the piezoelectric bars, a metal layer is suitably deposited (e.g., as a blanket metal layer) to cover the exposed surfaces, such as the upper surface of patterned piezoelectric layer, sidewalls of the piezo bars, exposed surface of the one or more intermediate layers, and the like. Then, lithography and etch processes can be used to pattern the blanket metal layer into patterned conductive components, such as the electrodes on the sidewalls of the piezo bars, busbars on the piezoelectric layer. According to some exemplary aspects, overlaps of the electrodes and the piezo bars may exist due to limitations of the manufacturing process, such as alignment limitation of the lithography process.

FIG. 26 shows a cross-sectional view of the acoustic resonator structure 2300 along the section line C-C′ in FIG. 23A (e.g., the cut line that turns from X direction to Y direction and back to X direction) by the first exemplary manufacturing process after the metal layer is patterned (but before the cavity 2340 is formed) according to an exemplary aspect of the disclosure.

In the example of FIG. 26, the metal layer on the sidewalls that form the electrodes also overlaps with the piezoelectric bars. For example, the electrode E1 has an irregular polygon shape that has a wing portion 2335 that is extended onto the piezoelectric bar 2315E and overlaps on the piezoelectric bar 2315E.

In a second exemplary manufacturing process, the metal layer is formed by a first blanket metal layer and a second blanket metal layer. For example, after the piezoelectric layer on the one or more intermediate layers is pattered to form the piezoelectric bars, the photoresist that is used to define the piezoelectric bars is left on while the first blanket metal layer of the M1 layer is suitably deposited. The first blanket metal layer is deposited on various surfaces, such as on the photoresist left on the patterned piezoelectric layer, sidewalls of the piezoelectric bars, and exposed surface of the one or more intermediate layers. Then, the photoresist is lift-off to remove the first blanket metal layer on the photoresist. The first blanket metal layer remains on the sidewalls of the piezo bars and on the exposed surface of the one or more intermediate layers. Then, lithography and etch process can be used to remove the first blanket metal layer on the exposed surface of the one or more intermediate layers, and keep the first blanket metal layer on the sidewalls of the piezoelectric bars to form the electrodes. Further, similar pattern process that uses photoresist lift off process can be applied on the second blanket metal layer to form the metal layer on the patterned piezoelectric layer (e.g., busbars). According to some exemplary aspects, self-alignment of the electrodes to the piezo bars can be performed by the second exemplary manufacturing process.

FIG. 27 shows a cross-sectional view of the acoustic resonator structure 2300 along the section line C-C′ (e.g., a cut line that turns from X direction to Y direction and back to X direction) by the second exemplary manufacturing process after the M1 layer (including the first blanket metal layer and the second blanket metal layer) is patterned (but before the cavity 2340 is formed) according to an exemplary aspect of the disclosure.

In the example of FIG. 27, the metal layer on the sidewalls that form the electrodes is formed by patterning the first blanket metal layer 2337; and the metal layer on the piezoelectric layer 2310 is formed by patterning the second blanket metal layer 2338. In the example of FIG. 27, the electrode E1 may have an irregular shape, and the electrode E1 is self-aligned to the sidewall of the piezoelectric bar 2315E.

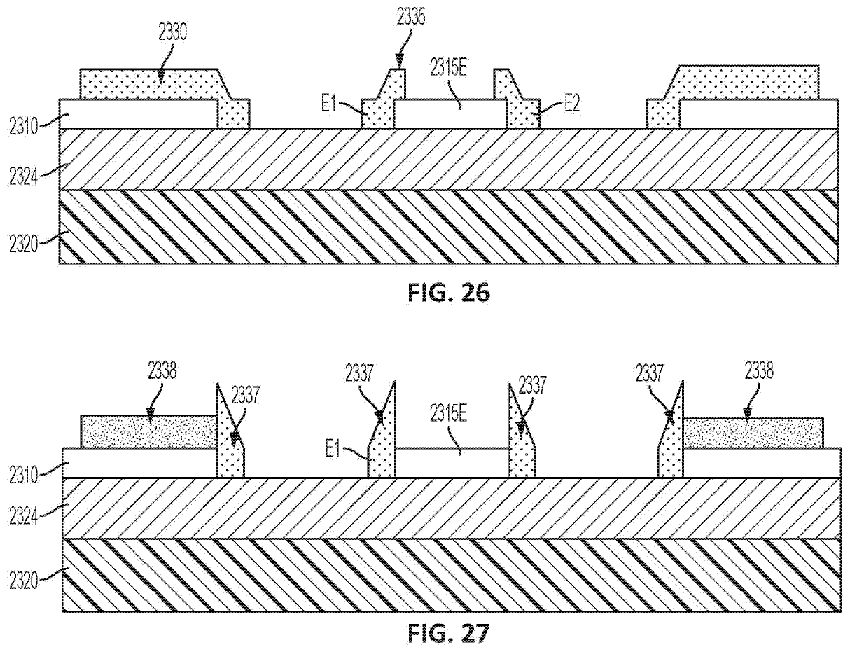

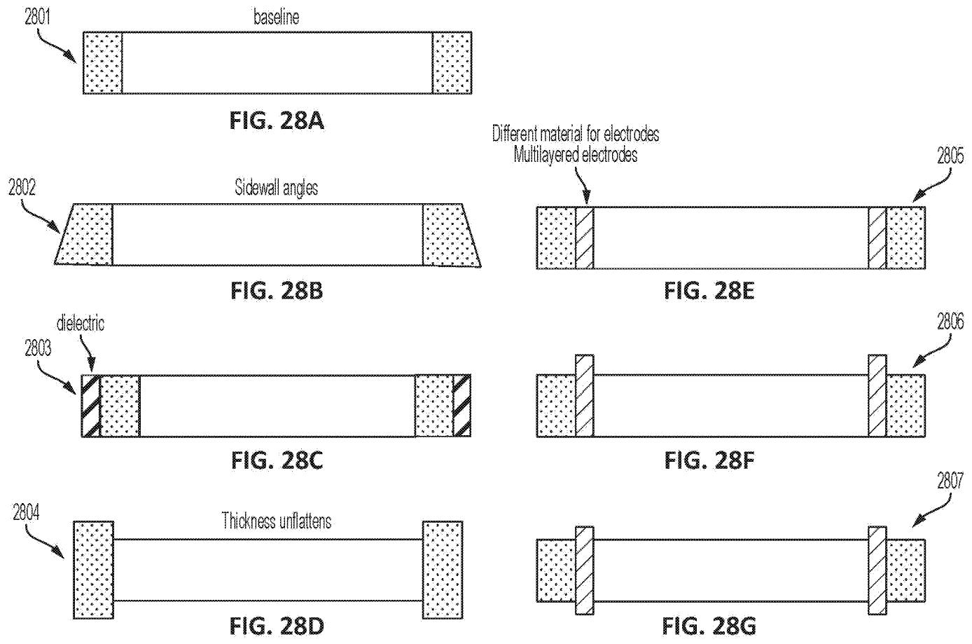

It is noted that variations can be made to the ARNs shown in FIGS. 23A-23D. FIGS. 28A-28G show cross-sectional views of an ARN, such the ARNs 2301-2305, according to some exemplary aspects of the disclosure.

FIG. 28A shows a cross-sectional view of an ARN 2801 that is about the same as the ARN 2305 in FIG. 23D. In this configuration, a metal layer on a sidewall of a respective piezoelectric bar that forms at least one electrode of the pair of electrodes (in this case both electrodes) of at least one nanowire of the plurality of nanowires aligns to the piezoelectric bar relative to the thickness direction.

FIG. 28B shows a cross-sectional view of an ARN 2802 that is a variation of the ARN 2801. The metal layer that forms the electrodes of the ARN 2802 has sidewall angles.

FIG. 28C shows a cross-sectional view of an ARN 2803 that is a variation of the ARN 2801. As shown, a dielectric layer can be disposed on out sides of the electrodes of the ARN 2803, which may be provided for spur suppression, for example. In other words, dielectric layer can be disposed on at least one electrode of the pair of electrodes and opposite the respective piezoelectric bar of ARN 2803 in an exemplary aspect.

FIG. 28D shows a cross-sectional view of an ARN 2804 that is a variation of the ARN 2801. The thickness of the electrodes of the ARN 2804 are unflattened, and can protrude in a direction to be higher than the piezo bar, and/or protrude in a direction to be lower than the piezo bar.

FIG. 28E shows a cross-sectional view of an ARN 2805 that is a variation of the ARN 2801. The electrodes of the ARN 2805 are formed of multiple conductive layers, and the multiple conductive layers can be flattened of about the same thickness as the piezo bar.

FIG. 28F shows a cross-sectional view of an ARN 2806 that is a variation of the ARN 2805. The electrodes of the ARN 2806 are formed of multiple conductive layers, and the multiple conductive layers can have different thickness, for example one of the multiple conductive layers can protrude in a direction to be higher than the piezo bar.

FIG. 28G shows a cross-sectional view of an ARN 2807 that is a variation of the ARN 2805. The electrodes of the ARN 2807 are formed of multiple conductive layers, and the multiple conductive layers can have different thickness, for example one of the multiple conductive layers can protrude in a direction to be higher than the piezo bar and protrude in a direction to be lower than the piezo bar.

Thus, according to the exemplary aspects shown above with respect to FIG. 23A to FIG. 28G, exemplary aspects of a laterally-excited bulk acoustic wave resonator are provided. In general, the exemplary device is an acoustic resonator that is built on a substrate (e.g., a silicon substrate with a buried oxide (SiO₂ BOX) intermediate layer) in which a piezoelectric layer (e.g., lithium niobate) is patterned into an array of discrete, freestanding bars (i.e., piezoelectric bars). Each piezoelectric bar forms a nanowire structure that is patterned from the piezoelectric layer and is suspended over a cavity formed by releasing the underlying one or more dielectric layers through a vapor etching, for example. Each piezoelectric bar is sandwiched on its two lateral sidewalls by metal (M1) electrodes that apply the electric field in the lateral direction (i.e., the X-axis direction), which is orthogonal to the substrate thickness direction (i.e., the Z-axis direction).

In the fabricated embodiment, the widths of piezoelectric bar can range from approximately 1.0 to 3.0 μm, the thicknesses of the electrodes (e.g., the M1 fingers) can be approximately 300 nm, and the gap between neighboring piezoelectric bars can range from approximately 2.0 to 4.0 μm. By suspending each piezoelectric bar over a released cavity and driving it through truly laterally-directed electric fields, the exemplary acoustic resonator structure avoids the curved, non-uniform field lines inherent in top/bottom electrode arrangements such as those used in existing XBAR resonators, which results in an electric-field distribution that more closely approximates a parallel-plate capacitor oriented along the resonator's active dimension to thereby maximize electromechanical coupling.

A central design degree of freedom in the exemplary laterally-excited bulk acoustic wave resonators is the polarity relationship between adjacent electrode fingers of neighboring nanowire structures. In a first embodiment illustrated in FIGS. 23A to 23D, the two electrodes facing each other across the gap between neighboring nanowire structures carry opposite polarities (i.e., one face of the gap is positive and the facing face is negative), creating a continuous, unidirectional electric field that drives the piezoelectric bars coherently across the array.

In a second embodiment illustrated in FIGS. 24A to 24C, the adjacent facing electrodes across the gap carry the same polarity, so that the electric field between those faces is directed outward from both sides of the gap. In this same-polarity configuration, the shared metal layer deposited on the sidewalls of two neighboring piezoelectric bars within the inter-bar gap can form a single, electrically continuous electrode serving both nanowire structures simultaneously. Depending on process execution, that metal layer may cover all sidewalls in the gap or may leave one or more sidewalls partially exposed. Similarly, the metal layer may extend over the top of the piezoelectric bar forming so-called wing portions or an overlapping protrusion as an artifact or deliberate result of the blanket metal deposition and patterning sequence. It is noted that while the overlapping configuration may slightly reduce electrical resistance and is generally preferred from a performance standpoint, a flush-aligned configuration is equally achievable through photolithographic control of the resist edge.

Because each individual nanowire structure is a mechanically independent acoustic resonator (i.e., it is excited laterally and suspended over its own released cavity), a plurality of nanowire structures are connected in parallel to achieve the desired static capacitance (C₀) and power-handling capability, precisely analogous to the individual ribbon or nanowire approach used in the related ARN architecture described above. This independence of the resonating cells enables pitch chirping across the electrode array. By varying the pitch (i.e., the total lateral width of a composite electrode-bar-electrode cell) from one nanowire to the next along the length direction of the array, parasitic spurious resonances can be spectrally spread and suppressed without meaningfully perturbing the main resonant mode, since there are no collective wave propagation effects linking one nanowire to its neighbor as there would be in a conventional SAW device. This represents a significant advantage for filter applications where out-of-band spur suppression is critical.

Finally, in the exemplary laterally-excited bulk acoustic wave resonators described herein, a dielectric layer can be provided between the lateral electrode and the sidewall of the piezoelectric bar to provide additional degrees of freedom for tuning the resonant frequency, managing temperature coefficient of frequency (TCF), or protecting the piezoelectric sidewall during fabrication. It should also be appreciated that while a single metal layer is described to provide the conductive patterns, multi-layer electrode stacks (M1 plus M2) can be implemented to enable independent optimization of the sidewall-contact electrode and any overlying interconnect or busbar metallization, as well as the possibility of coating the outer faces of the piezoelectric bars with a dielectric on the exterior side to achieve additional TCF compensation. Together, these embodiments define a resonator platform that retains the high-coupling advantage of laterally directed electric fields, the fabrication flexibility of established thin-film MEMS processes, and a rich set of structural and compositional variables enabling broad optimization across frequency, coupling coefficient, spur behavior, and thermal stability.

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. An acoustic resonator, comprising:
a substrate including a base and a cavity extending in a thickness direction thereof; and
a piezoelectric layer coupled to the substrate, wherein the piezoelectric layer includes a plurality of nanowire structures that each comprise:
a piezoelectric bar that extends in a first direction over the cavity, and
a pair of electrodes, each electrode of the pair of electrodes disposed on an opposite side of the piezoelectric bar to sandwich the piezoelectric bar in a second direction that is substantially perpendicular to the first direction and substantially orthogonal to a thickness direction of the substrate,
wherein at least two neighboring nanowire structures of the plurality of nanowire structures have a gap therebetween in the second direction.

2. The acoustic resonator of claim 1, wherein adjacent neighboring electrodes of the at least two neighboring nanowire structures that face each other across the gap are configured to have opposite polarities from each other.

3. The acoustic resonator of claim 1, wherein adjacent neighboring electrodes of the at least two neighboring nanowire structures that face each other across the gap are configured to have a same polarity as each other.

4. The acoustic resonator of claim 3, wherein, for the at least two neighboring nanowire structures that face each other across the gap, a metal layer extends on sidewalls of the respective piezoelectric bars and in the gap to face each other to form the adjacent neighboring electrodes of the at least two neighboring nanowire structures.

5. The acoustic resonator of claim 4, wherein all sidewalls in the gap are covered by the metal layer.

6. The acoustic resonator of claim 1, wherein a metal layer on a sidewall of a respective piezoelectric bar that forms at least one electrode of the pair of electrodes of at least one nanowire structure of the plurality of nanowire structures extends over the respective piezoelectric bar to partially overlap a top surface of the piezoelectric bar.

7. The acoustic resonator of claim 1, wherein a metal layer on a sidewall of a respective piezoelectric bar that forms at least one electrode of the pair of electrodes of at least one nanowire of the plurality of nanowires aligns to the piezoelectric bar relative to the thickness direction.

8. The acoustic resonator of claim 1, wherein a pitch of the plurality of nanowire structures varies in the second direction.

9. The acoustic resonator of claim 1, further comprising a dielectric layer on at least one electrode of the pair of electrodes opposite the respective piezoelectric bar of at least one nanowire structure of the plurality of nanowire structures.

10. The acoustic resonator of claim 1, wherein:
the substrate further comprises at least one intermediate layer having the cavity,
the piezoelectric layer is coupled to the substrate via the at least one intermediate layer, and
the piezoelectric bar of at least a portion of the plurality of nanowire structures extends over the cavity in the thickness direction.

11. A bandpass filter, comprising
a plurality of acoustic resonators, at least one acoustic resonator of the plurality of acoustic resonators including:
a substrate including a base and a cavity extending in a thickness direction thereof; and
a piezoelectric layer coupled to the substrate, wherein the piezoelectric layer includes a plurality of nanowire structures that each comprise:
a piezoelectric bar that extends in a first direction over the cavity, and
a pair of electrodes, each electrode of the pair of electrodes disposed on an opposite side of the piezoelectric bar to sandwich the piezoelectric bar in a second direction that is substantially perpendicular to the first direction and substantially orthogonal to a thickness direction of the substrate,
wherein at least two neighboring nanowire structures of the plurality of nanowire structures have a gap therebetween in the second direction.

12. The bandpass filter of claim 11, wherein, for the at least one acoustic resonator, adjacent neighboring electrodes of the at least two neighboring nanowire structures that face each other across the gap are configured to have opposite polarities from each other.

13. The bandpass filter of claim 11, wherein, for the at least one acoustic resonator, adjacent neighboring electrodes of the at least two neighboring nanowire structures that face each other across the gap are configured to have a same polarity as each other.

14. The bandpass filter of claim 13, wherein, for the at least two neighboring nanowire structures that face each other across the gap, a metal layer extends on sidewalls of the respective piezoelectric bars and in the gap to face each other to form the adjacent neighboring electrodes of the at least two neighboring nanowire structures.

15. The bandpass filter of claim 11, wherein, for the at least one acoustic resonator, a metal layer on a sidewall of a respective piezoelectric bar that forms at least one electrode of the pair of electrodes of at least one nanowire structure of the plurality of nanowire structures extends over the respective piezoelectric bar to partially overlap a top surface of the piezoelectric bar.

16. The bandpass filter of claim 11, wherein, for the at least one acoustic resonator, a metal layer on a sidewall of a respective piezoelectric bar that forms at least one electrode of the pair of electrodes of at least one nanowire of the plurality of nanowires aligns to the piezoelectric bar relative to the thickness direction.

17. The bandpass filter of claim 11, wherein, for the at least one acoustic resonator, a pitch of the plurality of nanowire structures varies in the second direction.

18. The bandpass filter of claim 11, wherein the at least one acoustic resonator further comprises a dielectric layer on at least one electrode of the pair of electrodes opposite the respective piezoelectric bar of at least one nanowire structure of the plurality of nanowire structures.

19. The bandpass filter of claim 11, wherein, for the at least one acoustic resonator:
the substrate further comprises at least one intermediate layer having the cavity,
the piezoelectric layer is coupled to the substrate via the at least one intermediate layer, and
the piezoelectric bar of at least a portion of the plurality of nanowire structures extends over the cavity in the thickness direction.

20. A radio frequency module comprising:
a filter device including a plurality of acoustic resonators; and
a radio frequency circuit coupled to the filter device, the filter device and the radio frequency circuit being enclosed within a common package, wherein at least one acoustic resonator of the plurality of acoustic resonators of the filter device includes:
a substrate including a base and a cavity extending in a thickness direction thereof; and
a piezoelectric layer coupled to the substrate, wherein the piezoelectric layer includes a plurality of nanowire structures that each comprise:
a piezoelectric bar that extends in a first direction over the cavity, and
a pair of electrodes, each electrode of the pair of electrodes disposed on an opposite side of the piezoelectric bar to sandwich the piezoelectric bar in a second direction that is substantially perpendicular to the first direction and substantially orthogonal to a thickness direction of the substrate,
wherein at least two neighboring nanowire structures of the plurality of nanowire structures have a gap therebetween in the second direction.
